(19) United States
(12) Patent Application Publication
(10) Pub. No.: US 2025/0198958 A1
(43) Pub. Date: Jun. 19, 2025

(54) SYSTEM AND METHOD TO DETECT MECHANICALLY DAMAGED ENERGY STORAGE CELLS USING ELECTRICAL SIGNALS

(71) Applicant: Temple University-Of The Commonwealth System of Higher Education, Philadelphia, PA (US)

(72) Inventors: Damoon Soudbakhsh, Philadelphia, PA (US); Elham Sahraei, Philadelphia, PA (US); Mohsen Derakhshan, Philadelphia, PA (US)

(21) Appl. No.: 18/851,894

(22) PCT Filed: Mar. 29, 2023
(86) PCT No.: PCT/US23/65095

§ 371 Date: Sep. 27, 2024

Related U.S. Application Data
(60) Provisional application No. 63/324,799, filed on Mar. 29, 2022.

(51) Int. Cl. G01N 27/02; G01R 31/367; G01R 31/389; H01M 10/42

(52) U.S. Cl. CPC G01N 27/026; G01R 31/367; G01R 31/389; H01M 10/4285

(57) ABSTRACT

A system for detecting mechanically damaged energy storage devices comprises an analyzer, a battery electrically connected to the analyzer, and a computing system communicatively connected to the analyzer and/or battery. A method for detecting mechanically damaged energy storage devices comprises applying an input at a range of frequencies to an energy storage device, measuring an output from the energy storage device, performing Electrochemical Impedance Spectroscopy (EIS) with Dynamic Relaxation Time (DRT) to calculate an impedance spectrum of the energy storage device, and modeling the energy storage device based on the impedance spectrum to identify if the energy storage device is mechanically damaged.

### CROSS-REFERENCE TO RELATED APPLICATIONS

This application claims priority to U.S. provisional application No. 63/324,799 filed on Mar. 29, 2022, incorporated herein by reference in its entirety.

### STATEMENT REGARDING FEDERALLY SPONSORED RESEARCH OR DEVELOPMENT

This invention was made with government support under N000141912351 awarded by the Office of Naval Research. The government has certain rights in the invention.

### BACKGROUND OF THE INVENTION

Lithium-ion batteries (LiBs) pose severe hazards if their safety is compromised. Prior work has shown that mechanical damage to the battery may not affect its voltage, capacity, or other primary specifications. Therefore, currently, there is no method to check the integrity of battery cells inside an electric vehicle battery pack once it has been subjected to a shock or impact. Disclosed herein is a method based on measuring the frequency spectra of LiBs. The analysis can be performed either analytically, such as determining the time constants from the measured spectra, or through machine learning if more data is available.

There has been a significant effort to determine time constants associated with internal processes of energy storage devices such as electrode and electrolyte processes. Distribution of relaxation times (DRT) has been suggested as such a method to separate time constants of relaxation mechanisms by mapping the frequency domain measurements to the time constant-domain. One of the first applications of DRT to energy storage systems was presented by Franklin et al, where a Fast Fourier Transform (FFT) deconvolution was used (see A. D. Franklin and H. J. De Bruin, “The Fourier analysis of impedance spectra for electroded solid electrolytes,” Phys. Stat. Sol. (a), vol. 75, no. 2, pp. 647-656, February 1983). The DRT method was originally developed using a series of Voigt elements. DRT has gained notable attention in the past decade to study the time constants of energy storage systems (ESS). DRT is usually found from impedance spectra obtained using Electrochemical Impedance Spectroscopy (EIS). Determining DRT from EIS data is an ill-posed inverse problem and a variety of inversion methods have been suggested to obtain DRT from EIS measurement data such as Tikhonov Regularization (TR). Tikhonov Regularization requires tuning some parameters that have a direct effect on the output DRT including: the number of the time constant, the type of the basis function, regularization penalty functions, and regularization parameters (λ). The small values of λ result in more peaks, with several appearing with no connections to the physics. On the other hand, large values of λ merge the peaks causing ambiguity in differentiating the time constants that are close to each other. Finding an optimal value of this parameter is not trivial and it is a subject of ongoing research. Several cost functions, such as Discrepancy and Cross-Validation, have been suggested to determine λ. However, these methods have difficulties when applied to the experimental data to analyze the time constants of LIBs.

Thus, there is a need in the art for systems and methods of detecting and quantifying damage sustained by energy storage systems and evaluating their safety.

### SUMMARY OF THE INVENTION

Some embodiments of the invention disclosed herein are set forth below, and any combination of these embodiments (or portions thereof) may be made to define another embodiment.

In one aspect, a system for detecting mechanical damage in energy storage devices comprises an impedance analyzer, an electrical terminal electrically connected to the analyzer, and a computing system communicatively connected to the analyzer or the electrical terminal, comprising a processor and a non-transitory computer-readable medium with instructions stored thereon, which when executed by a processor, perform steps comprising, performing Electrochemical Impedance Spectroscopy (EIS) with Dynamic Relaxation Time (DRT) to calculate an impedance spectrum of an energy storage device connected to the battery terminal, and modeling the energy storage device based on the impedance spectrum to identify if the energy storage device is mechanically damaged.

In one embodiment, the system further comprises an environment chamber. In one embodiment, the environment chamber is configured to control the environmental conditions surrounding the energy storage device and the temperature of the energy storage device. In one embodiment, the system is configured to identify damaged energy storage devices via Electrochemical Impedance Spectroscopy (EIS) and Dynamic Relaxation Time (DRT) methods. In one embodiment, the system is configured to perform EIS with DRT at a frequency greater than or equal to 1000 Hz.

In one embodiment, the system is configured to model the energy storage device based on only a portion of the EIS spectrum. In one embodiment, the portion of the EIS spectrum is a high-frequency portion in the range of 0.1 kHz to 100 kHz. In one embodiment, the portion of the EIS spectrum is a high-frequency portion in the range of 2 kHz to 47 kHz. In one embodiment, the determination of if the energy storage device is safe is based on DRT or a machine learning method.

In another aspect, a method for detecting mechanical damage in energy storage devices comprises applying an input at a range of frequencies to an energy storage device, measuring an output from the energy storage device, performing Electrochemical Impedance Spectroscopy (EIS) with Dynamic Relaxation Time (DRT) to calculate an impedance spectrum of the energy storage device, and modeling the energy storage device based on the impedance spectrum to identify if the energy storage device is mechanically damaged.

In one embodiment, the applied input is a voltage or current. In one embodiment, the applied input is in sinusoidal or pulsed form. In one embodiment, the output from the energy storage device is a voltage or current. In one embodiment, the method further comprises the step of changing a temperature of the energy storage device to a specific temperature. In one embodiment, a mechanically damaged energy storage device is identified in less than 60 seconds. In one embodiment, a mechanically damaged energy storage device is identified in less than 30 seconds. In one embodiment, the method further comprises performing EIS on a frequency range to derive a temperature of the energy storage device based on the state of charge of the energy storage device. In one embodiment, the method is performed in situ. In one embodiment, the method further comprises the step of calculating a state of charge (SOC) of the energy storage device. In one embodiment, the method further comprises the step of calculating a state of health (SOH) of the energy storage device. In one embodiment, the method further comprises the step of calculating an age of the energy storage device. In one embodiment, the EIS with DRT is performed at a frequency greater than or equal to 1000 Hz. In one embodiment, the method is non-invasive and non-destructive. In one embodiment, the method is performed while the energy storage device is in an operational mode to eliminate downtime. In one embodiment, the method is performed in situ.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1A depicts a schematic of an exemplary lithium-ion battery (LIB) in accordance with some embodiments.

FIG. 1B is a block diagram depicting an example system for detecting mechanically damaged energy storage devices using electrical signals in accordance with some embodiments.

FIG. 2A and FIG. 2B show exemplary Voigt and Modified Voigt circuits, respectively, in accordance with some embodiments.

FIG. 2C depicts an exemplary procedure to find optimal regularization parameters in accordance with some embodiments.

FIG. 3 is a flow chart depicting an exemplary method for detecting mechanically damaged energy storage devices using electrical signals in accordance with some embodiments.

FIG. 4 depicts an exemplary computing system in accordance with some embodiments.

FIG. 5 is a plot showing example experimental control results for EIS of an experimental lithium-ion cell (cell CE) with T=23° C. and 0% State of Charge (SOC) in accordance with some embodiments.

FIGS. 6A through 6D are plots of experimental results showing the effect of A on the DRT cost functions of cell CE at 0% SOC for various temperatures in accordance with some embodiments. FIG. 6A shows the normalized discrepancy, FIG. 6B shows SSE, FIG. 6C shows normalized cross-validation, and FIG. 6D shows normalized cross-discrepancy.

FIG. 7 depicts optimal A selection for 0% SOC cell CE in accordance with some embodiments.

FIGS. 8A through 8F depict experimental results for DRT temperature and SOC dependencies for 0% and 100% SOC cell CE in accordance with some embodiments.

FIG. 9 is a plot of experimental results showing impedance spectra between a damaged cell and an intact cell at room temperature (22° C.) and cycle number 106 in accordance with some embodiments.

FIG. 10 is a plot of experimental results showing impedance spectra between a damaged cell and an intact cell at a low temperature (−20° C.) and cycle number 106 in accordance with some embodiments.

FIG. 11 is a plot of experimental results showing impedance spectra between a damaged cell and an intact cell at a high temperature (40° C.) and cycle number 106 in accordance with some embodiments.

FIGS. 12A through 12C depict experimental results of force/voltage versus displacement in indentation experiments in accordance with some embodiments.

FIGS. 13A through 13F depict experimental results of DRT of control cells at room temperature in accordance with some embodiments.

FIGS. 14A through 14F depict experimental results of DRT of damaged cells at room temperature in accordance with some embodiments.

FIGS. 15A through 15D depicts experimental criteria to determine λ* for cell CE at T=+20C and their impact on the number of peaks and the reconstructed EIS in accordance with some embodiments.

FIGS. 16A through 16D depict the trend of the peaks of the DRT outputs for P_{C} and P_{H} in control and indentation experiments in accordance with some embodiments.

FIG. 17 depicts the procedure of the experiment and data acquisition steps in accordance with some embodiments.

### DETAILED DESCRIPTION OF THE INVENTION

It is to be understood that the figures and descriptions of the present invention have been simplified to illustrate elements that are relevant for a clearer comprehension of the present invention, while eliminating, for the purpose of clarity, many other elements found in systems and methods of detecting mechanically damaged energy storage cells using electrical signals. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Ranges: throughout this disclosure, various aspects of the invention can be presented in a range format. It should be understood that the description in range format is merely for convenience and brevity and should not be construed as an inflexible limitation on the scope of the invention. Where appropriate, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, and 6. This applies regardless of the breadth of the range.

As used herein, battery, cell, and similar descriptions all relate to energy storage devices.

Referring now in detail to the drawings, in which like reference numerals indicate like parts or elements throughout the several views, in various embodiments, presented herein are systems and methods of detecting mechanically damaged energy storage cells using electrical signals. Further details can be found in M. Derakhshan et al., “Detecting mechanical indentation from the time constants of Li-ion batteries”, Cell Reports Physical Science, Volume 3, Issue 11, 2022, and hereby incorporated herein by reference in its entirety.

Disclosed herein are novel methods and systems to detect mechanical damage in energy storage systems, sometimes referred to herein as energy storage cells. One example of an energy storage system suitable for use with the systems and methods herein is a lithium-ion battery, which may comprise one or more individual lithium-ion cells. The same approach can be used for other advanced energy storage systems such as, for example, Li-air, sodium battery, Solid-state, flow battery, and fuel cell. These novel methods enable a safety evaluation of Li-ion batteries. The methods are based on applying inputs in the form of voltage or current to Li-ion batteries and measuring current or voltage as the output. The inputs can be in sinusoidal form. The measurements are used to differentiate damaged batteries from intact ones. The tests are non-destructive, and the batteries can be returned to service if they pass the evaluation.

Further disclosed are a system and a method to evaluate the conditions of energy storage devices, particularly Li-ion batteries. The technical solution method is non-invasive and non-destructive and allows evaluation of the safety of the Li-ion batteries. This is done by applying electrical signals to the batteries at a range of frequencies and using the collected data.

Energy storage devices such as Li-ion batteries are present in many devices from cellphones to electric vehicles and airplanes. They can be dangerous during operation as undetected damages can lead to unpredicted (sudden) failures and even fire and explosion. While in many applications the focus is on protecting batteries from mechanical loading and impact, damage can still happen during operation, storage, manufacturing, or assembly.

The method is non-destructive, and the cells can be tested in their operating range. The method is based on measuring impedance spectra of the cells. This data can be measured and analyzed at different conditions, such as at different temperatures, and/or by using representative models and machine learning techniques. In one approach, time-constants of the batteries and their associated magnitudes are used to infer information about the cells such as their State of Charge (SOC) and safety status.

Furthermore, presented herein are new criteria to choose the regularization parameter to determine the time constants of the internal processes of the energy storage devices. EIS data was collected for three cylindrical cells at temperatures ranging from −20° C. to +40° C., and ridge regression was used to determine the time constants. The regularization parameters were selected based on the introduced criteria. The time constants determined using the disclosed method can guide the control-oriented data driven models as well as the equivalent circuit models of ESS. For example, the number of time constants can determine the minimum number of elements to model ESS as well as the range of frequency at which these elements are excited. Furthermore, the time constants (and the basis function) can be used for distributed modeling of ESS with many elements and also for fault detection and health monitoring.

### Lithium-Ion Battery

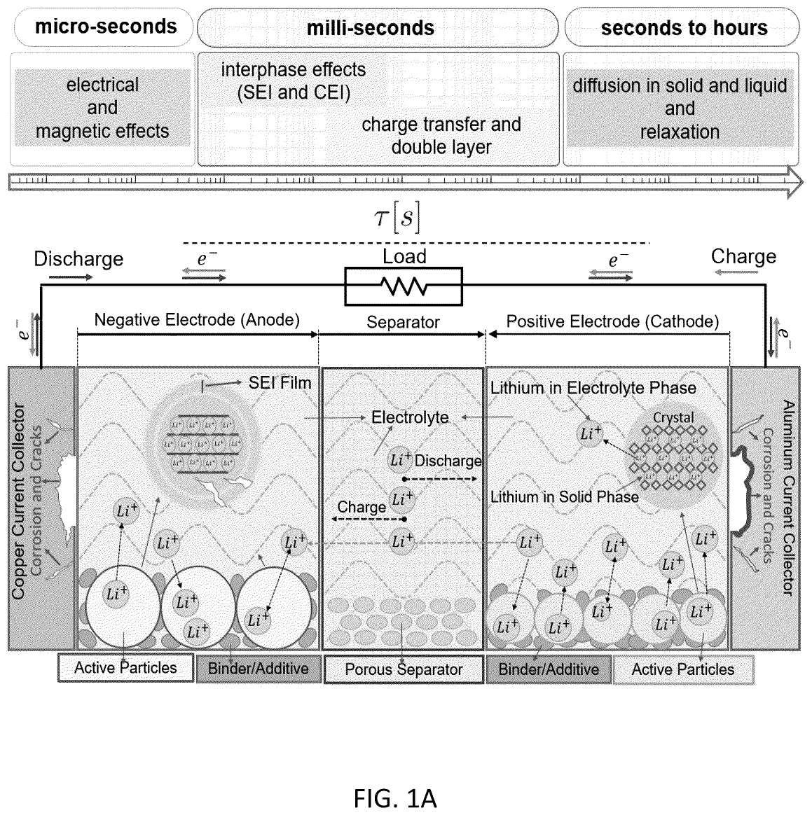

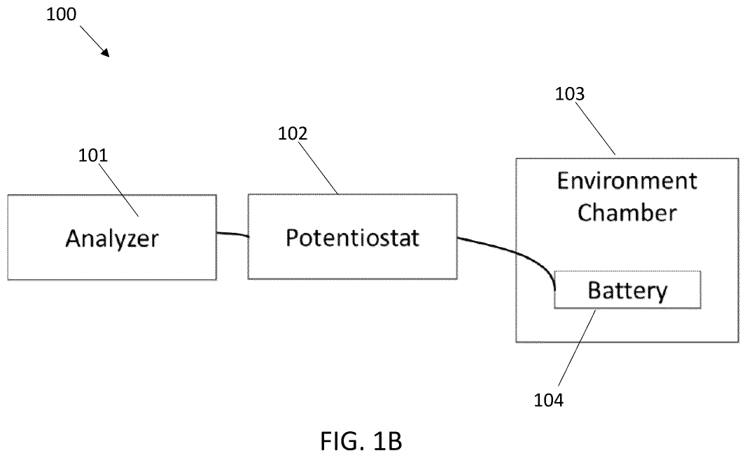

A schematic of the main components of LIBs, including a cathode, anode, separator, electrolyte, and current collectors, is shown in FIG. 1A. Each electrode comprises active particles to store the lithium, which is the electrode's main function. Anodes are commonly graphite or silicon based, and cathodes are often lithium metal oxide-based crystals. Binders and additives keep the electrode components together, reinforce the structure, increase contacts, and enhance electrodes' electronic conductivity. LIBs have several internal processes that contribute to their response to electrical excitations. Some mechanisms, such as charge transfer, double layer effect, diffusion, and Li-ion intercalation can be considered the properties of the materials and design of the cells (such as the thickness of the electrodes). In contrast, processes, such as solid electrolyte interphase (SEI), lithium plating, cathode electrolyte interphase (CEI), corrosion and cracks, electrolyte decomposition, and oxidation are primarily associated with cycling aging, damages, and degradations. There is a frequency range associated with each of these internal processes that are most active. These frequency ranges are identified with representative time constants by utilizing impedance spectra.

### Electrochemical Impedance Spectroscopy (EIS)

Electrochemical impedance spectroscopy (EIS) experiments are conducted and an advanced method is applied to detect time constants associated with each internal process to investigate the effect of different excitation and environmental conditions on these time constants (see Soudbakhsh, D., Gilaki, M., Lynch, W., Zhang, P., Choi, T., and Sahraei, E. (2020). Electrical response of mechanically damaged lithium-ion batteries. Energies 13, 4284. https://doi.org/10.3390/en13174284.). The primary tool for analyzing EIS data is developing distributed equivalent circuit models. However, the choice of model is a challenging task and limits the quality of analysis and results. In this research the EIS data was analyzed using the distribution of relaxation times (DRT) method to decouple the time constants of the batteries to characterize their health and safety.

DRT has been suggested to map the frequency domain measurements to time constant domain analysis by separating the time constants of different relaxation mechanisms. One of the first applications of DRT to energy storage systems has been presented where a fast Fourier transform deconvolution was used. DRT has gained considerable attention in the past decade to study the time constants of energy storage systems. While the DRT has been used to discuss the time constants of the Li-ion cells, most of the theories related to DRT have been developed based on simplified models, such as ZARC elements, and used on simulations or experimental cells. However, commercial cells have more complex dynamics due to electrochemical processes, such as charge transfer, SEI, and solid-state diffusion with overlapping frequency responses. Therefore, some assumptions in obtaining DRT are not valid for actual LIBs. For example, a common assumption in analyzing DRT is that the EIS plots start and end at the real axis, which does not hold for production cells.

Determining DRT from EIS data is an ill-posed inverse problem, and a variety of inversion methods have been suggested to obtain DRT from EIS measurement data, such as Tikhonov regularization (TR), preconditioned ridge regularization, Fourier transform, m(RQ) fit, Monte Carlo methods, maximum entropy methods, and genetic programming. TR is the most popular approach as it can be recast as a constrained quadratic programming problem and has connections to Bayesian statistics. However, TR has several parameters, such as the number of the time constants, the type of basis function, the penalty function, and the regularization parameter that directly affect the outputs. Small values of the regularization parameter (λ) increase the number of detected peaks, with several appearing without connections to the physics. On the other hand, large values of λ merge the peaks (fewer peaks), which causes ambiguity in differentiating the time constants that are close to each other. Several cost functions have been suggested to determine λ.

### System for Detecting Mechanically Damaged Energy Storage Cells

FIG. 1B shows a block diagram of a system 100 for detecting mechanically damaged energy storage cells. In some embodiments, the system 100 includes an analyzer 101, an optional potentiostat 102 communicatively connected to the analyzer 101, and battery to be measured 104 electrically connected to the potentiostat 102 and or the analyzer 101. In some embodiments, the battery 104 is located in an environment chamber 103 configured to control the environmental conditions surrounding the battery 104. In some embodiments, a computing system, such as computing system 400 described below, is communicatively connected to the analyzer 101, the optional potentiostat 102, battery 104, and/or environment chamber 103. In some embodiments, the computing system may be configured to collect and record one or more parameters of the battery and/or environment chamber during testing, for example temperature, humidity, barometric pressure, and the like. In some embodiments, the computing system may be configured to control one or more parameters of the environment chamber. In some embodiments, the computing system may be configured to return data measured by the potentiostat and/or the analyzer.

### Electrochemical Impedance Spectroscopy (EIS)

Electrochemical Impedance Spectroscopy (EIS) is a test based on applying sinusoidal inputs (E(ω): potential) with frequency ω to the cells and measure current as a function of frequency, I(ω). The ratio of the input E(ω) to output I(ω) and the phase shift between the two results in a frequency-dependent complex number Z(ω) called impedance:

$$Z ( ω ) = \frac{E ( ω )}{I ( ω )} \qquad ( 1 )$$

EIS analysis involves plotting the Imaginary part of the impedance Z″(ω) versus its real part Z′(ω), which is also known as Nyquist diagram. Typically, EIS is shown as the negative of the imaginary values versus the real parts.

1.) EIS plots provide the response of the system to a wide range of frequencies. However, due to the presence of several processes inside ESS, the interpretation of EIS data is a challenging task (see B. A. Boukamp, “Distribution (function) of relaxation times, successor to complex nonlinear least squares analysis of electrochemical impedance spectroscopy?” J. Phys. Energy, vol. 2, no. 4, p. 042001, August 2020.).

Kramers-Kronig relations state that if four conditions of causality, stability, linearity, and finiteness of the response are satisfied for a system, then the imaginary component and real component of the impedance are interdependent (see D. Soudbakhsh, M. Gilaki, W. Lynch, P. Zhang, T. Choi, and E. Sahraei, “Electrical Response of Mechanically Damaged Lithium-ion Batteries,” Energies, vol. 13, no. 17, 2020.). Therefore, one can compute imaginary (or real part) with information from frequency and the real component (imaginary component) of the impedance.

### The Distribution of Relaxation Times (DRT)

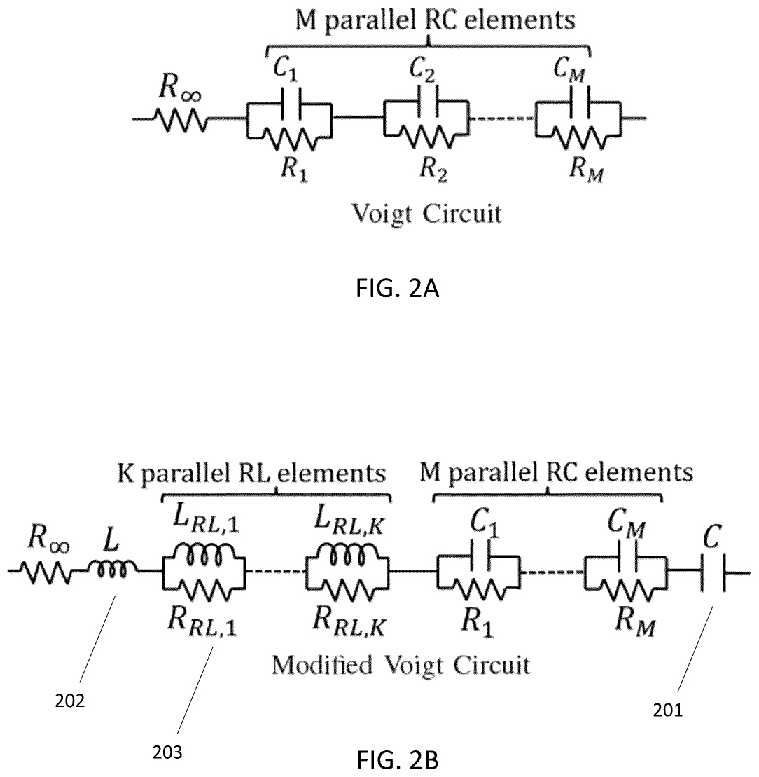

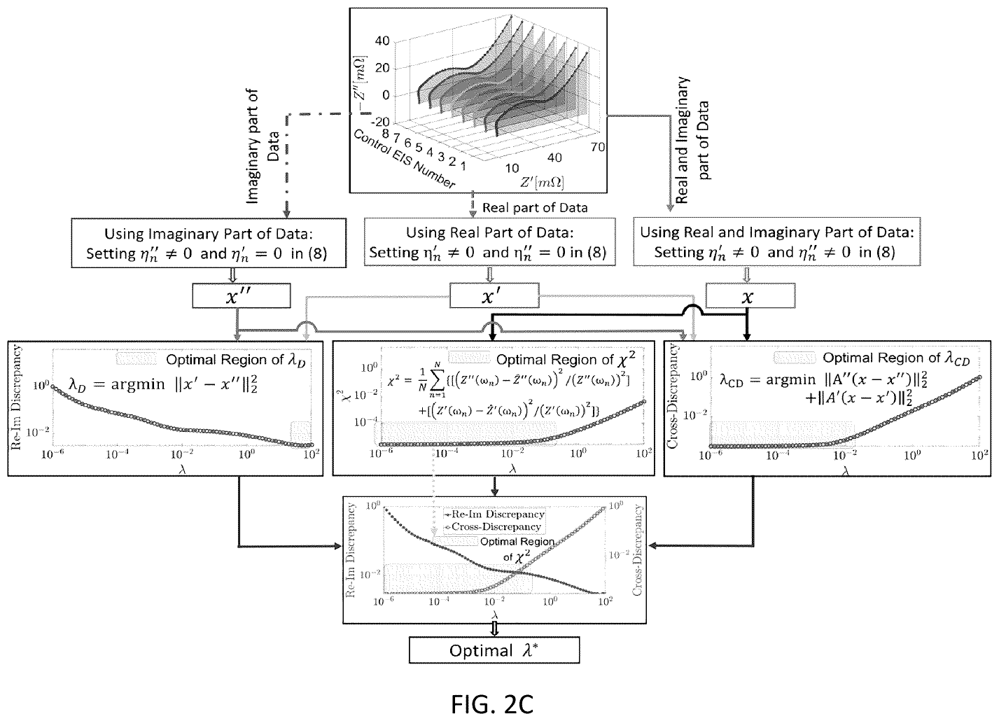

Each of the internal processes of LIBs is most active within a specific range of frequencies. DRT is a method to distinguish the time constants of different internal processes. The most common basis function for DRT is the Voigt circuit in series with an ohmic resistance R_{∞}, as shown in FIG. 2A. Each RC element corresponds to a semi-circle in the EIS plot (similar to the Nyquist diagram) and has a time constant τᵢ=RᵢCᵢ. However, each process is active at a wide range of frequencies, and many semi-circles are needed to represent the impedance spectra of the distributed processes of electrochemical systems. In the DRT analysis, a collection of RC elements, each with a time constant τᵢ, show the distributed time constants of each cell's internal process. The time constant associated with each peak is used as the representative time constant of each process.

DRT method can decouple the processes by identifying the time constants of the EIS data. A common DRT approach is to use an ohmic resistance R_{∞} in series with a Voigt Circuit (see H. Schichlein, A. C. M. Ller, and M. Voigts, “Deconvolution of electrochemical impedance spectra for the identification of electrode reaction mechanisms in solid oxide fuel cells,” J. Appl. Electrochem., vol. 32, no. 8, pp. 875-882, 2002) as shown in FIG. 2A. Each parallel RC element in this figure has a time constant τᵢ=RᵢCᵢ. Each element corresponds to a semi-circle in the EIS plot (similar to the Nyquist Diagram). However, a single (or few) semi-circle(s) cannot represent the impedance spectra of the distributed processes of electrochemical systems. Therefore, instead of exhibiting a single-time constant for each process, the cells exhibit continuous (distributed) time constants, which include of a collection of τᵢ's with a distribution. Consider a resistor in series with an inductor, in series with a large number of parallel RC and RL elements as shown in FIG. 2B to model the cell's impedance response. Using this model, the time constants, and their associated weights, one can identify distinguished peaks associated with internal processes of ESS.

First consider using a simple model as shown in FIG. 2A with M parallel RC elements in series with R_{∞}, and later add the rest of the elements as in FIG. 2B. The estimated impedance of the system \hat{Z}(ωₙ) at frequency ωₙ is derived as:

$$\hat{Z} ( {ω}_{n} ) = {R}_{∞} + {\sum }_{i = 1}^{M} \frac{{R}_{i}}{1 + j {ω}_{n} {τ}_{i}} \qquad ( 2 )$$

where j=\sqrt{−1}, and Rᵢ and Cᵢ are the resistance and capacitance of the i^{th} element, and τᵢ=RᵢCᵢ is its time constant. The mapping from the frequency-domain measurements to the time constant domain is obtained using the Fredholm integral of the first kind (see M. Saccoccio, T. H. Wan, C. Chen, and F. Ciucci, “Optimal Regularization in Distribution of Relaxation Times applied to Electrochemical Impedance Spectroscopy: Ridge and Lasso Regression Methods—A Theoretical and Experimental Study,” Electrochim. Acta, vol. 147, pp. 470-482, November 2014.):

$$Z ( ω ) = {\int }_{a}^{b} K ( ω , τ ) g ( τ ) d τ \qquad ( 3 )$$

where Z(ω) is the measured impedance in the frequency domain, g(τ) is the real-valued function of the distributed time constants, and K(ω, τ) is the kernel function. By having K(ω, τ) and Z(ω), one can obtain g(τ) through an inversion. Using infinite RC elements (M→∞) in series with R_{∞}, integral relation (Equation 3) can be rewritten as:

$$\hat{Z} ( {ω}_{n} ) = {R}_{∞} + {\int }_{0}^{∞} \frac{g ( τ )}{1 + j ωτ} d τ \qquad ( 4 )$$

where 1/(1+jωτ) is the kernel function and \hat{Z}(ω) is the reconstructed impedance, which in the ideal situation matches the measured impedance Z(ω). Since the EIS data are usually measured in a logarithmic scale, the common change of variables y=ln(τ) and γ(γ)=τg(τ) was used. Using these parameters, and separating the real and imaginary components, Equation 4 can be rewritten as:

$$\hat{Z} ( {ω}_{n} ) = {R}_{∞} + {\int }_{- ∞}^{∞} \frac{1}{1 + {( ω τ )}^{2}} γ ( ln τ ) d ln τ - j {\int }_{- ∞}^{∞} \frac{ω τ}{1 + {( ω τ )}^{2}} γ ( ln τ ) d ln τ \qquad ( 5 )$$

where γ(lnτ) is the DRT function, and a Ridge Regression will be used to find it as discussed below.

To solve Equation 5, one can discretize γ(Inτ) as a linear combination of the finite basis functions as follows:

$$γ ( ln τ ) = {\sum }_{i = 1}^{M} {χ}_{i} {ϕ}_{i} ( ln τ ) + {e}_{γ} ( ln τ ) \qquad ( 6 )$$

where ϕ(lnτ) is the i^{th} basis function, Xᵢ's are unknown weighting parameters for the basis function, and e_{z}(lnτ) is the discretization error. The result of plugging Equation 6 into Equation 5 gives:

$$\hat{Z} ( X , ω ) = {R}_{∞} + {\sum }_{i = 1}^{M} ( {χ}_{i} A - j {χ}_{i} B ) + {e}_{z} ( ln τ ) \qquad ( 7 )$$

$$where$$

$$A = {\int }_{- ∞}^{∞} ( \frac{1}{1 + {( ω τ )}^{2}} {ϕ}_{i} ( ln τ ) ) d ln τ$$

$$B = {\int }_{- ∞}^{∞} ( \frac{ω τ}{1 + {( ω τ )}^{2}} {ϕ}_{i} ( ln τ ) ) d ln τ$$

Equation 7 yields a good fit if both ends of the impedance (high and low frequency) converge to the real axis. However, in many applications including in LIBs, this assumption does not hold. Therefore, with reference to FIG. 2B, a modified version was used that includes a capacitor (201) C, to model low-frequency response (see M. A. Danzer, “Generalized Distribution of Relaxation Times Analysis for the Characterization of Impedance Spectra,” Batteries, vol. 5, no. 3, p. 53, July 2019.), an inductance (202), L, and a series of parallel RL elements 203 to model the high-frequency part of the EIS. For the chosen basis function (RC), ϕᵢ(lnτ)=δ(lnτ−lnτᵢ), the integrals in Equation 7 can be simplified to summation as in:

$$\hat{Z} ( X , ω ) = {e}_{z} ( ln τ ) + {R}_{∞} + j ω L + j \frac{1}{ω C} + {\sum }_{k = 1}^{K} {x}_{R L , k} ( \frac{{( ω {τ}_{R L , k} )}^{2}}{1 + {( ω {τ}_{RL , k} )}^{2}} + j \frac{ω {τ}_{RL , k}}{1 + {( ω {τ}_{R L , k} )}^{2}} ) + {\sum }_{i = 1}^{M} {χ}_{i} ( \frac{1}{1 + {( ω {τ}_{i} )}^{2}} - j \frac{ω {τ}_{i}}{1 + {( ω {τ}_{i} )}^{2}} ) \qquad ( 8 )$$

where X=[X₁, X₂, . . . , X_{M}, X_{RL,1}, X_{RL,2}, . . . , X_{RL,K}]^{T}, τ_{RL,K}=(L_{RL,k}/R_{RL,k}) is the time constant of the k^{th} RL elements, and R_{RL,k}=X_{RL,k}. The following regularization cost function was then minimized:

$$min . 𝒥 ( X ) = {\sum }_{n = 1}^{N} ( {{η}_{n}^{′} ( {Z}^{′} ( {ω}_{n} ) - {\hat{Z}}^{′} ( X , {ω}_{n} ) )}^{2} + {{η}_{n}^{″} ( {Z}^{″} ( {ω}_{n} ) - {\hat{Z}}^{″} ( X , {ω}_{n} ) )}^{2} ) + λ P ( X ) \qquad ( 9 )$$

In Equation 9, Z′ and Z″ are the real and imaginary components of the experimental data, and \hat{Z}′ and \hat{Z}″ are the real and imaginary components of the estimated impedance using Equation 8, respectively. The weighting factors η′ₙ and η″ₙ are set to one or zero as discussed below. Define P(X)=X^{T}QX, with Q being the identity matrix with (M+K)×(M+K) dimension. Furthermore, by arranging the real and imaginary parts of summations on the right-hand side of Equation 8 into the matrices A′ and A″, one can define:

$${Z}^{′} ( X ) = {A}^{′} X + {R}_{∞} \qquad ( 10 )$$

$${Z}^{″} ( X ) = {A}^{″} X + j ω L + j \frac{1}{ω C} \qquad ( 11 )$$

Since the EIS data is validated using the Kramers-Kronig transforms, minimizing [symbol] can be achieved using real imaginary, or both components of the impedance (see D. Soudbakhsh, M. Gilaki, W. Lynch, P. Zhang, T. Choi, and E. Sahraei, “Electrical Response of Mechanically Damaged Lithium-ion Batteries,” Energies, vol. 13, no. 17, 2020.). The regularization parameter λ has a significant impact on the solutions.

DRT functions that minimize cost function (Equation 9) were then found. A model comprising of R, L, RL, RC, and C elements as shown in FIG. 2B and formulated in Equation 8 was used.

The number of time constants and the range of time constants affect the optimization problem. The EIS is measured at N data points, and the frequency points {ω₁, ω₂, . . . , ω_{N}}, are logarithmically distributed in descending order. Thus, the associated time constants are distributed in logarithmic scale in the range of τ₁=(1/ωₘₐₓ)<τ<τ_{M}=(1/ωₘᵢₙ), where M is the total number of time constants. The number of time constants should be at least equal to the number of frequency data points (M≥N) as the basis function, ϕᵢ, is a Dirac delta function.

In choosing the appropriate regularization parameter, note that larger values of A lead to smoother DRT that can mask some of the actual peaks (time constants). On the other hand, smaller values of λ lead to more peaks and introduce artificial time constants. In Saccoccio et al. (see M. Saccoccio, T. H. Wan, C. Chen, and F. Ciucci, “Optimal Regularization in Distribution of Relaxation Times applied to Electrochemical Impedance Spectroscopy: Ridge and Lasso Regression Methods—A Theoretical and Experimental Study,” Electrochim. Acta, vol. 147, pp. 470-482, November 2014.) two cost functions are suggested to quantify the optimal λ: (i) Re-Im Discrepancy function (Equation 12) and (ii) Re-Im Cross-Validation function (Equation 13):

$${λ}_{1} = arg min {‖ {X}^{′} - {X}^{″} ‖}_{2}^{2} \qquad ( 12 )$$

$${λ}_{2} = arg min {‖ {Z}^{′} - {A}^{′} {Z}^{″} ‖}_{2}^{2} + {‖ {Z}^{″} - {A}^{″} {X}^{′} ‖}_{2}^{2} \qquad ( 13 )$$

Another criterion that can be used to select λ is the Sum of the Squared Error (SSE), which is defined as:

$$S S E = {\sum }_{n = 1}^{N} ( {( {Z}^{′} ( {ω}_{n} ) - {\hat{Z}}^{′} ( {ω}_{n} ) )}^{2} + {( {Z}^{″} ( {ω}_{n} ) - {\hat{Z}}^{″} ( {ω}_{n} ) )}^{2} ) \qquad ( 14 )$$

Preliminary studies on LIBs did not yield to an acceptable λ using Equation 12 or Equation 13. However, by using Equations 12 and 14, and introducing Equation 15, more acceptable ranges for λ were obtained. The new cost function (Cross-Discrepancy) is the difference between the computed impedance using both real and imaginary, and the ones computed using only the real and only the imaginary components of the impedance, and defined as:

$${λ}_{3} = arg min {‖ {A}^{′} ( X - {X}^{′} ) ‖}_{2}^{2} + {‖ {A}^{″} ( X - {X}^{″} ) ‖}_{2}^{2} \qquad ( 15 )$$

where X is the calculated DRT by using both parts of the impedance in Equation 9.

### DRT of a Voigt Circuit

The mathematical model can alternatively be written and described as follows. In some embodiments, the DRT formulation is used to extract the time constants and polarizations of the cell by mapping the EIS data in the frequency domain to the time constant domain using the Fredholm integral of the first kind:

$$Z ( ω ) = {\int }_{a}^{b} K ( ω , τ ) g ( τ ) d τ \qquad ( 16 )$$

where, Z(ω) is the measured impedance spectra, g(τ) is the real-valued function of distributed time constant, and K(ω, τ) is a kernel function. By having K(ω, τ) and Z(ω), the DRT function g(τ) can be found using an inversion. Define the kernel function using electrical circuits as a basis function.

First shown is a DRT formulation of a circuit comprised of only resistors and capacitors, as shown in FIG. 2A. The rest of the elements will be added later below, as shown in FIG. 2B. Denote the number of parallel RC elements with M. These elements are in series with each other and an ohmic resistance R_{∞}. Denote the DRT reconstructed impedance of the cell by \hat{Z}(ωₙ) at each frequency ωₙ, which, using the equivalent impedance of the circuit of FIG. 2A, is estimated by:

$$\hat{Z} ( {ω}_{n} ) = {R}_{∞} + {\sum }_{i = 1}^{M} \frac{{R}_{i}}{1 + j {ω}_{n} {τ}_{i}} \qquad ( 17 )$$

where j=\sqrt{−1}, and τᵢ=RᵢCᵢ is the time constant of the i^{th} element, and Rᵢ and Cᵢ are its resistance and capacitance. If the numbers of RC elements are very large (M→∞), the summation in Equation 17 can be written in the integral form Equation 16 as:

$$\hat{Z} ( ω ) = {R}_{∞} + {\int }_{0}^{∞} \frac{g ( τ )}{1 + j ωτ} d τ \qquad ( 18 )$$

where 1/(1+jωτ) is the kernel function, and \hat{Z}(ω) is the reconstructed impedance, which in the ideal situation matches the measured impedance Z(ω). Since the EIS data are usually measured in a logarithmic scale, the common change of variable γ(ln(τ))=τg(τ) is used for easier exposition, and rewrite Equation 18 as:

$$\hat{Z} ( ω ) = {R}_{∞} + {\int }_{- ∞}^{∞} \frac{γ ( ln τ )}{1 + j ωτ} d ( ln τ ) \qquad ( 19 )$$

where γ(ln τ) gives the distribution of the relaxation times. To solve for γ(ln τ), the integral in Equation 19 is discretized and used a ridge regression approach. First, γ(ln τ) is approximated with a finite sum through using a basis function φᵢ(ln τ) as in

$$γ ( ln τ ) = {\sum }_{i = 1}^{M} {X}_{RC , i} {φ}_{i} ( ln τ ) + {e}_{γ} ( ln τ ) \qquad ( 20 )$$

In Equation 20, X_{RC,i} is an unknown weighting parameter for the basis function φᵢ(ln τ), M is the number of time constants, and e_{z}(In τ) is the discretization error. Then, the integral in Equation 19 can be rewritten as:

$$\hat{Z} ( {X}_{R C} , ω ) = {R}_{∞} + {\sum }_{i = 1}^{M} {X}_{R C , i} ( {\int }_{- ∞}^{∞} ( \frac{{φ}_{i} ( ln τ )}{1 + j ωτ} ) d ln τ ) + {e}_{z} ( ln τ ) \qquad ( 21 )$$

with X_{RC}=[X_{RC,1}, X_{RC,2}, . . . , X_{RC,M}]^{T}. Note that using RC elements as the basis function results in the Dirac delta function, i.e.,

$${φ}_{i} ( ln τ ) = δ ( ln \frac{τ}{{τ}_{i}} ) .$$

Then, the DRT problem solves for the weights X_{RC,i} at each τᵢ.

### DRT of the Modified Voigt Circuit

The DRT derivations and formulations (Equation 21) of the previous section were based on the assumption that the imaginary component of the impedance converges to zero at the lowest and highest frequencies. However, the EIS graph of the actual LIBs does not converge to the real axis on either side due to the presence of several processes, such as diffusion. Therefore, the formulation is modified with additional elements, as shown in FIG. 2B. The additional elements include an inductor (L), K number of RL circuits, and a capacitor (C). Using these elements, one arrives at:

$$\hat{Z} ( X , ω ) = {R}_{∞} + j ω L + j \frac{1}{ω C} + {\sum }_{k = 1}^{K} {X}_{RL , k} \frac{j {ωτ}_{R L , k}}{1 + j ω {τ}_{R L , k}} + {\sum }_{i = 1}^{M} {x}_{RC , i} ( {\int }_{- ∞}^{∞} ( \frac{δ ( ln \frac{τ}{{τ}_{i}} )}{1 + j ω τ} ) d ln τ ) + {e}_{z} ( ln τ ) \qquad ( 22 )$$

where

$$X = {[ {X}_{R C} , {X}_{R L} ]}^{T} and {X}_{R L} = {[ {X}_{RL , 1} , {X}_{R L , 2} , … , {X}_{R L M} ]}^{T} . {τ}_{R L , k} = \frac{{L}_{RL , i}}{{R}_{RL , k}}$$

is the time constant of the k^{th} RL elements. By manipulating Equation 22 one can separate the real and imaginary parts of the impedance and rearrange them in a matrix form.

To minimize the error between the measured impedance, Z(ω), and the reconstructed impedance, \hat{Z}(X, ω), without over-fitting, the following common objective function was used:

$${J}_{0} ( X ) {=}^{def} {\sum }_{n = 1}^{N} ( {{η}_{n}^{′} ( {Z}^{′} ( {ω}_{n} ) {\hat{Z}}^{′} ( X , {ω}_{n} ) )}^{2} + {{η}_{n}^{″} ( {Z}^{″} ( {ω}_{n} ) - {\hat{Z}}^{″} ( X , {ω}_{n} ) )}^{2} ) + λ P ( X ) \qquad ( 23 )$$

where Z′ and Z″ are real and imaginary parts of experiment data, respectively. The weighting factors ηₙ′ and ηₙ″ are set to one or zero as discussed below. A quadratic regularization cost P(X)=X^{T}I_{(M+K)}X is used, with I_{(M+K)} denoting the identity matrix with dimension (M+K)×(M+K).

### DRT Variables

The optimization problem in Equation 23 has several degrees of freedom in terms of formulating the problem and tuning the parameters that affect the solution. Discussed here are these parameters and the rationale/criteria for choosing them.

The choice of the basis function affects the DRT solution. Here, passive electrical components were chosen, as shown in FIGS. 2A-2B as the basis function. While there are several other basis functions, such as piece-wise linear and radial basis function, using passive elements have more clear connections to the physics.

The number of time constants and their range are other factors affecting the optimization problem. These parameters are related to the data collection and accuracy of the device, and measuring very low frequencies (<10 mHz) using EIS is not practical. Furthermore, the EIS data are typically collected on a logarithmic scale, such as ten data points in each frequency decade. The number of data points associated with measured impedance spectra at frequencies ωₙ is denoted by N. Since these data points are distributed in a logarithmic scale in frequency and they are collected from high to low frequencies, the time constants are also distributed in logarithmic scale in the range of

$${τ}_{1} = \frac{1}{{ω}_{max}} < τ < {τ}_{M} = \frac{1}{{ω}_{min}} ,$$

where M is the number of time constants. The range of time constants is typically extended to the nearest decade points (i.e., 0.003 ms and 300 s) associated with measured impedance spectra. Also, instead of using the same data points as in the measured impedance spectra for the time constants, a finer resolution is used for time constants by interpolating more points between the measurements, hence M≥N. The regularization parameter λ is another degree of freedom with a significant effect on the distribution of the time constants and their heights.

### Optimal Regularization Parameter

The regularization parameter, λ in Equation 23, has a significant effect on the DRT function. The large value of λ leads to smoother DRT with fewer peaks as they merge. On the other hand, small values of λ result in more (and potentially artificial) peaks, and the DRT shows more oscillations.

Several criteria and associated cost functions have been suggested to optimize the regularization parameter λ. These criteria mostly take advantage of Kramers-Kronig transforms, which states that real and imaginary impedance components are inter-dependent if some requirements are met in the system and measurements. These criteria typically result in very large or small values of λ, when applied to LIBs. Here, is disclosed a set of three criteria to determine the optimal λ [symbol] λ* of LIBS.

The first cost function used in determining λ* is the Re-Im discrepancy cost function (see Saccoccio, M., Wan, T. H., Chen, C., and Ciucci, F. (2014). Optimal regularization in distribution of relaxation times applied to electrochemical impedance spectroscopy: ridge and lasso regression methods—a theoretical and experimental study. Electrochim. Acta 147, 470-482. https://doi.org/10.1016/j.electacta. 2014.09.058.), which minimizes the difference in the computed DRT using real components of the impedance, X′, versus the DRT computed using the imaginary component of the impedance, X″. The process to obtain these parameters is shown in FIG. 2C. Therefore, λ_{D} that minimizes the Re-Im discrepancy cost function can be found using:

$${λ}_{D} = argmin {‖ {X}^{′} - {X}^{″} ‖}_{2}^{2} \qquad ( 24 )$$

The second cost function minimizes the error between the reconstructed EIS and the measured impedance spectra. While some previous studies use the sum of squared errors (SSE), the disclosed method uses a complex weighted sum of squared errors (χ²) to minimize the errors of both imaginary and real components of the reconstructed impedance simultaneously. This cost function is defined as:

$${χ}^{2} = \frac{1}{N} {\sum }_{i = 1}^{n} ( \frac{{( {Z}^{′} ( {ω}_{n} ) - {\hat{Z}}^{′} ( {ω}_{n} ) )}^{2}}{{( {Z}^{′} ( {ω}_{n} ) )}^{2}} + \frac{{( {Z}^{″} ( {ω}_{n} ) - {\hat{Z}}^{″} ( {ω}_{n} ) )}^{2}}{{( {Z}^{″} ( {ω}_{n} ) )}^{2}} ) \qquad ( 25 )$$

A third cost function was used to minimize the discrepancy between the computed impedance using both real and imaginary components of the measured impedance (A′X,A″X) and the computed impedance computed using only the real (or imaginary) components of EIS (A′X′ and A″X″). A′ and A″ are real and imaginary parts of summations in Equation 22 in the matrix form as given below. Define this as the cross-discrepancy cost function, and the regularization parameter that minimizes is:

$${λ}_{CD} = argmin {‖ {A}^{′} ( X - {X}^{′} ) ‖}_{2}^{2} + {‖ {A}^{″} ( X - {X}^{″} ) ‖}_{2}^{2} \qquad ( 26 )$$

where, λ_{CD} is the optimal λ calculated using the cross-discrepancy cost function. FIG. 2C shows the disclosed procedure to find the λ using these cost functions. The procedure starts by computing X′, X″, and X at different λ values. Then, these values are used to obtain the curves of the Re-Im discrepancy, cross-discrepancy, and χ² versus λ. The optimal λ* is a trade-off of these functions and is close to the intersection of Re-Im discrepancy and cross-discrepancy (λₒ). λ>λₒ, was chosen before a significant increase in χ².

### Method for Detecting Mechanically Damaged Energy Storage Cells

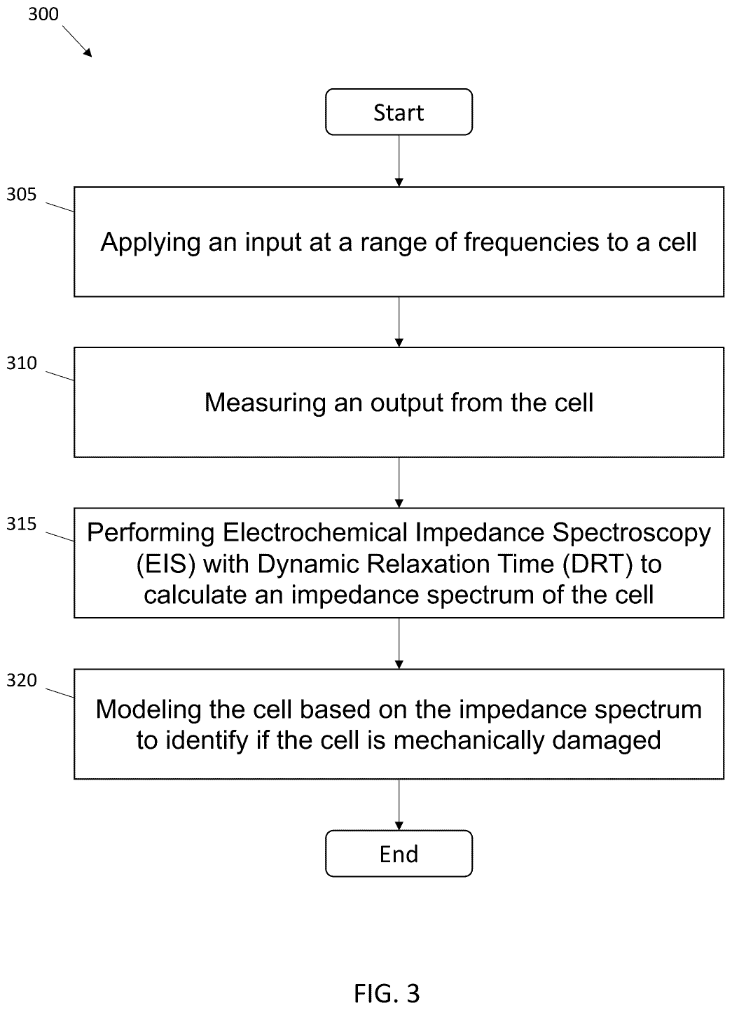

FIG. 3 shows a flow chart depicting a method 300 for detecting mechanically damaged energy storage cells.

The method 300 starts at Operation 305, where an input is applied at a range of frequencies to a cell. At Operation 310 an output from the cell is measured. At Operation 315 Electrochemical Impedance Spectroscopy (EIS) with Dynamic Relaxation Time (DRT) is performed to calculate an impedance spectrum of the cell. The method 300 ends at Operation 320, where the cell is modeled based on the impedance spectrum to identify if the cell is mechanically damaged. In some embodiments, DRT is combined with modeling to identify bad cells. In some embodiments, the method 300 is configured for real-time measurements, such as for analyzing cells after an impact. For example, energy storage cells in a vehicle can be monitored for safety after an impact.

In some embodiments, the method 300 utilizes high-frequency (i.e., greater than 1000 Hz) EIS measurement. By utilizing high frequencies, the measurement can be performed in a few seconds or less as opposed to days and/or weeks when EIS is done at lower frequencies. Furthermore, mechanical damage to the cell affects the high frequency data.

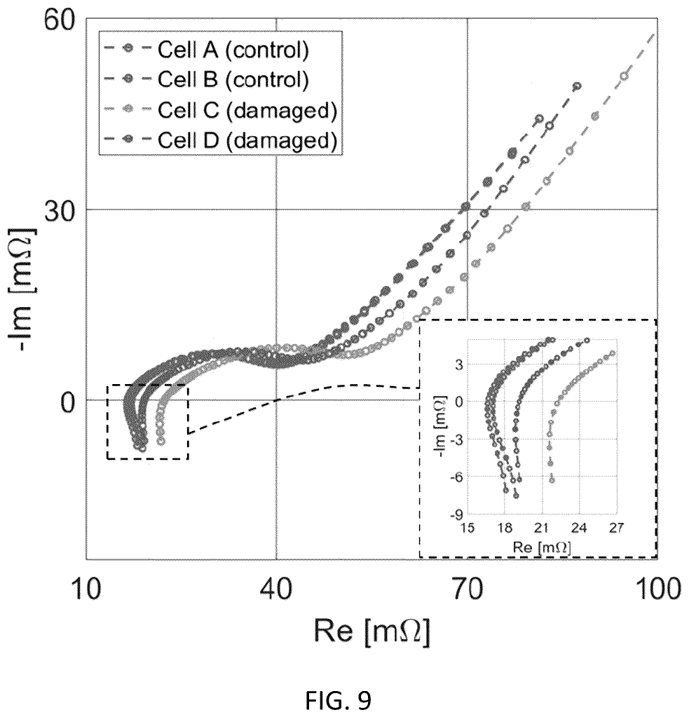

In some embodiments, the method 300 is utilized to perform impedance spectra measurements on batteries after cooling/warming them to specific set temperatures to determine their safety status. In such a case, the battery 104 needs to first be transported to an environmental chamber 103 that can change the temperature of the battery 104 to the desired value, then impedance spectra should be applied and analyzed for detection of damage (see FIG. 1B). The inputs can be of various types such as sinusoidal and/or pulse shapes. An example of how the temperature affects the response of mechanically damaged cells compared to the intact cells is shown in FIGS. 9-11.

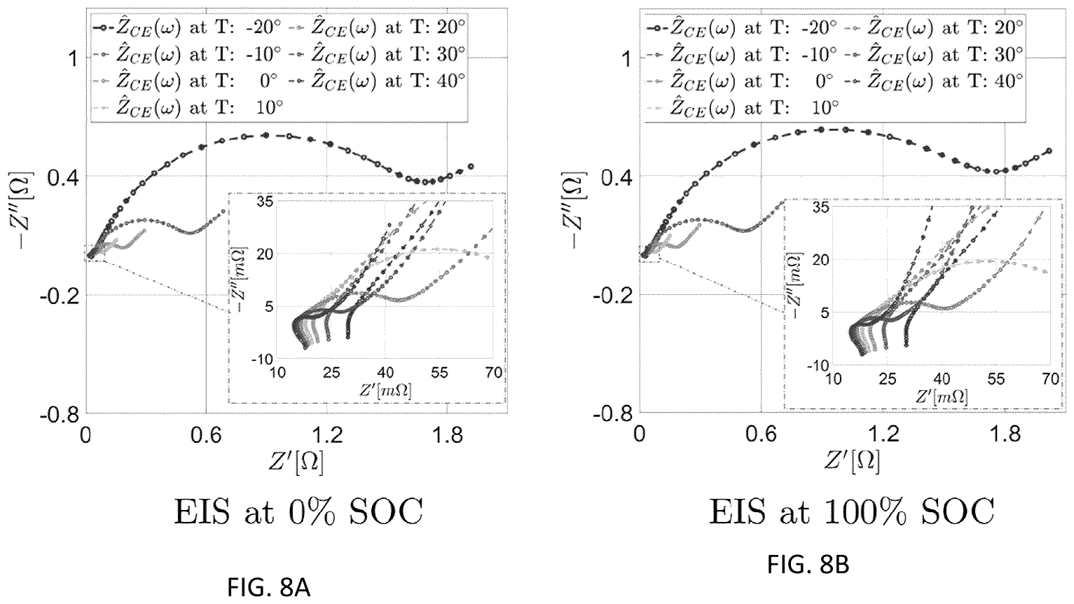

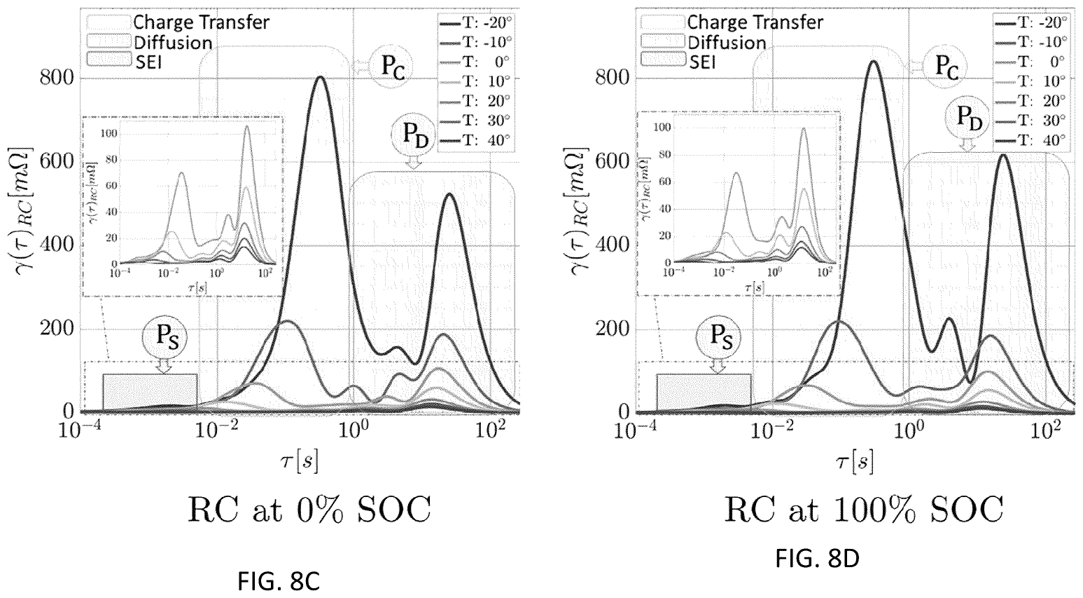

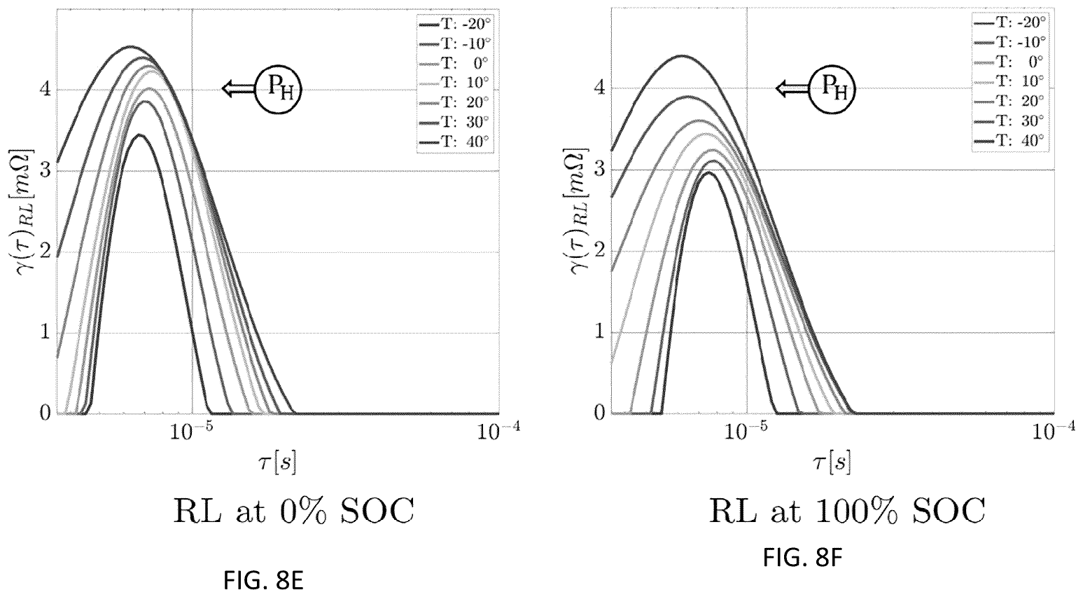

In some embodiments, the method 300 is utilized to perform impedance spectra measurements on the batteries 104 in situ, without any need for an environmental chamber 103. In this case, after recording the spectra, an advanced analysis is applied to the result to extract the time constants of the system. The time constants then are used to make predictions about the safety of the battery 104. FIGS. 8C-F, 13C-F, 14C-F, and 16A-D show examples where the time constants can be used to extract information about the battery 104.

The method 300 and system 100 provide the following benefits. In some embodiments, the method 300 is non-invasive and non-destructive, so that the cells and modules can be returned to service if they pass the test. In some embodiments, the method 300 is fast and efficient, as there is no need to take CT-scan or other expensive and slow methods to detect the damage. In some embodiments, the testing and analysis performed in method 300 is done while the system is in operational mode with no required downtime. In some embodiments, the system 100 to perform method 300 is portable since the system 100 requires small equipment and can be moved easily. In some embodiments, the method 300 provides for increased safety of energy systems and the useful life of their energy storage devices as they can stay in service without fear of fire and other hazards due to undetected mechanical damages.

### Computing Environment

In some aspects of the present invention, software executing the instructions provided herein may be stored on a non-transitory computer-readable medium, wherein the software performs some or all of the steps of the present invention when executed on a processor.

Aspects of the invention relate to algorithms executed in computer software. Though certain embodiments may be described as written in particular programming languages, or executed on particular operating systems or computing platforms, it is understood that the system and method of the present invention is not limited to any particular computing language, platform, or combination thereof. Software executing the algorithms described herein may be written in any programming language known in the art, compiled or interpreted, including but not limited to C, C++, C#, Objective-C, Java, Javascript, MATLAB, Python, PHP, Perl, Ruby, or Visual Basic. It is further understood that elements of the present invention may be executed on any acceptable computing platform, including but not limited to a server, a cloud instance, a workstation, a thin client, a mobile device, an embedded microcontroller, a television, or any other suitable computing device known in the art.

Parts of this invention are described as software running on a computing device. Though software described herein may be disclosed as operating on one particular computing device (e.g. a dedicated server or a workstation), it is understood in the art that software is intrinsically portable and that most software running on a dedicated server may also be run, for the purposes of the present invention, on any of a wide range of devices including desktop or mobile devices, laptops, tablets, smartphones, watches, wearable electronics or other wireless digital/cellular phones, televisions, cloud instances, embedded microcontrollers, thin client devices, or any other suitable computing device known in the art.

Similarly, parts of this invention are described as communicating over a variety of wireless or wired computer networks. For the purposes of this invention, the words “network”, “networked”, and “networking” are understood to encompass wired Ethernet, fiber optic connections, wireless connections including any of the various 802.11 standards, cellular WAN infrastructures such as 3G, 4G/LTE, or 5G networks, Bluetooth®, Bluetooth® Low Energy (BLE) or Zigbee® communication links, or any other method by which one electronic device is capable of communicating with another. In some embodiments, elements of the networked portion of the invention may be implemented over a Virtual Private Network (VPN).

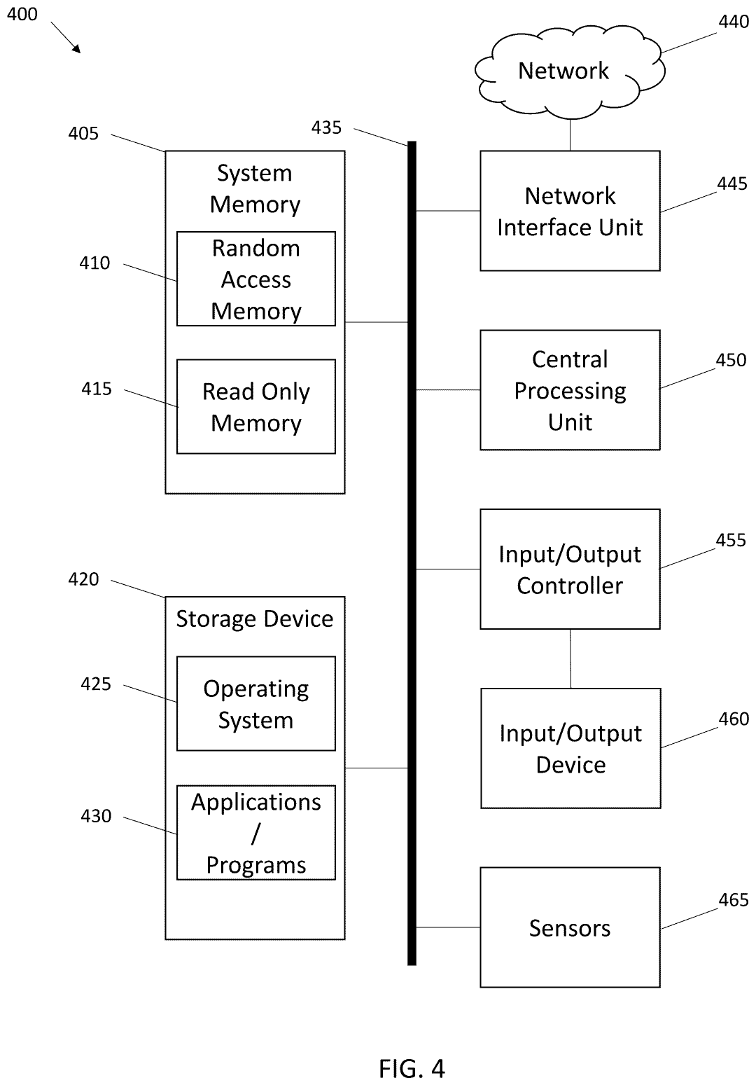

FIG. 4 and the following discussion are intended to provide a brief, general description of a suitable computing environment in which the invention may be implemented. While the invention is described above in the general context of program modules that execute in conjunction with an application program that runs on an operating system on a computer, those skilled in the art will recognize that the invention may also be implemented in combination with other program modules.

Generally, program modules include routines, programs, components, data structures, and other types of structures that perform particular tasks or implement particular abstract data types. Moreover, those skilled in the art will appreciate that the invention may be practiced with other computer system configurations, including hand-held devices, multiprocessor systems, microprocessor-based or programmable consumer electronics, minicomputers, mainframe computers, and the like. The invention may also be practiced in distributed computing environments where tasks are performed by remote processing devices that are linked through a communications network. In a distributed computing environment, program modules may be located in both local and remote memory storage devices.

FIG. 4 depicts an illustrative computer architecture for a computer 400 for practicing the various embodiments of the invention. The computer architecture shown in FIG. 4 illustrates a conventional personal computer, including a central processing unit 450 (“CPU”), a system memory 405, including a random-access memory 410 (“RAM”) and a read-only memory (“ROM”) 415, and a system bus 435 that couples the system memory 405 to the CPU 450. A basic input/output system containing the basic routines that help to transfer information between elements within the computer, such as during startup, is stored in the ROM 415. The computer 400 further includes a storage device 420 for storing an operating system 425, application/program 430, and data.

The storage device 420 is connected to the CPU 450 through a storage controller (not shown) connected to the bus 435. The storage device 420 and its associated computer-readable media, provide non-volatile storage for the computer 400. Although the description of computer-readable media contained herein refers to a storage device, such as a hard disk or CD-ROM drive, it should be appreciated by those skilled in the art that computer-readable media can be any available media that can be accessed by the computer 400.

By way of example, and not to be limiting, computer-readable media may comprise computer storage media. Computer storage media includes volatile and non-volatile, removable and non-removable media implemented in any method or technology for storage of information such as computer-readable instructions, data structures, program modules or other data. Computer storage media includes, but is not limited to, RAM, ROM, EPROM, EEPROM, flash memory or other solid state memory technology, CD-ROM, DVD, or other optical storage, magnetic cassettes, magnetic tape, magnetic disk storage or other magnetic storage devices, or any other medium which can be used to store the desired information and which can be accessed by the computer.

According to various embodiments of the invention, the computer 400 may operate in a networked environment using logical connections to remote computers through a network 440, such as TCP/IP network such as the Internet or an intranet. The computer 400 may connect to the network 440 through a network interface unit 445 connected to the bus 435. It should be appreciated that the network interface unit 445 may also be utilized to connect to other types of networks and remote computer systems.

The computer 400 may also include an input/output controller 455 for receiving and processing input from a number of input/output devices 460, including a keyboard, a mouse, a touchscreen, a camera, a microphone, a controller, a joystick, or other type of input device. Similarly, the input/output controller 455 may provide output to a display screen, a printer, a speaker, or other type of output device. The computer 400 can connect to the input/output device 460 via a wired connection including, but not limited to, fiber optic, ethernet, or copper wire or wireless means including, but not limited to, Bluetooth, Near-Field Communication (NFC), infrared, or other suitable wired or wireless connections.

As mentioned briefly above, a number of program modules and data files may be stored in the storage device 420 and RAM 410 of the computer 400, including an operating system 425 suitable for controlling the operation of a networked computer. The storage device 420 and RAM 410 may also store one or more applications/programs 430. In particular, the storage device 420 and RAM 410 may store an application/program 430 for providing a variety of functionalities to a user. For instance, the application/program 430 may comprise many types of programs such as a word processing application, a spreadsheet application, a desktop publishing application, a database application, a gaming application, internet browsing application, electronic mail application, messaging application, and the like. According to an embodiment of the present invention, the application/program 430 comprises a multiple functionality software application for providing word processing functionality, slide presentation functionality, spreadsheet functionality, database functionality and the like.

The computer 400 in some embodiments can include a variety of sensors 465 for monitoring the environment surrounding and the environment internal to the computer 400. These sensors 465 can include a Global Positioning System (GPS) sensor, a photosensitive sensor, a gyroscope, a magnetometer, thermometer, a proximity sensor, an accelerometer, a microphone, biometric sensor, barometer, humidity sensor, radiation sensor, or any other suitable sensor.

### EXPERIMENTAL EXAMPLES

The invention is now described with reference to the following Examples. These Examples are provided for the purpose of illustration only and the invention should in no way be construed as being limited to these Examples, but rather should be construed to encompass any and all variations which become evident as a result of the teaching provided herein.

Without further description, it is believed that one of ordinary skill in the art can, using the preceding description and the following illustrative examples, make and utilize the present invention and practice the claimed methods. The following working examples therefore, specifically point out exemplary embodiments of the present invention, and are not to be construed as limiting in any way the remainder of the disclosure.

Shown herein are new criteria to determine DRT parameters and demonstrate its application in evaluating the safety of mechanically damaged Li-ion cells. Impedance spectra of intact and mechanically damaged Li-ion cells are measured. A distribution function of the relaxation times problem is formulated to determine the time constants of the cells and use the dependency of the peaks on temperature and SOC (state of charge) to assign them to major processes (diffusion, charge transfer, SEI, and the changes in the properties of the electrodes and separator). Comparing the DRT peaks of a control group and a mechanically indented group shows that, while the EIS and DRTs of the control group remained constant, there were changes in the DRT results as the extent of the mechanical damage increased. While the changes in the height of low- and mid-frequency peaks of the indented group are almost similar to the control groups, the changes in the height of the high-frequency peak are substantial. While the changes in this high-frequency peak height were less than 2.5% for the control group, it dropped by more than 36.0% during the indentation procedure, with most of the drop happening after 5 mm of indentation. Investigating the changes in voltage shows that the slope (drop) change started at around 5 mm, as the DRT analysis suggests. Note that this drop is less than 1 mV, which prohibits using voltage measurements as a health monitoring tool. However, the disclosed method can detect the eminence of the short circuit 2 mm before it actually happens. The disclosed method has the potential to quantify such damages non-invasively and allow the utilization of Li-ion cells for their second life or monitoring them after an impact in highly sensitive applications, such as electric cars and drones.

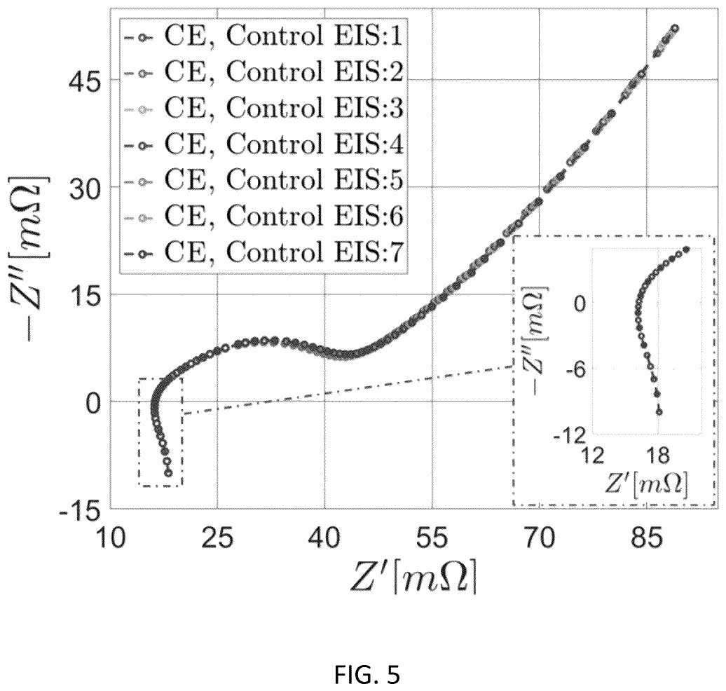

Referring now to FIGS. 5 through 8, exemplary experimental results are shown. Three 18650 cylindrical Lithium-ion cells (cells CE, CF, and CH) with graphite anode and Lithium Iron Phosphate (LiFePO₄) cathode were tested to determine and assign the DRT peaks to the electrochemical processes. The cells have a nominal capacity of 1.5 Ah. The cycling process started with the beginning of life experiments where five charge-discharge cycles with c/10 to a charge cutoff voltage of 3.65 V and a discharge cutoff voltage of 2.5 V were conducted before starting the cycling. After the initial characterization of the cells, the cells went through charge/discharge cycling at 1 C until they reached stable cycle-to-cycle EIS measurements.

The EIS experiments were performed at temperatures −20, 0, +20, and 40° C. in a thermal test chamber at 0% and 100% SOC. A four-electrode connection was used to collect the EIS data in the frequency range of 10 mHz to 47 kHz. For Cell CE, EIS responses at −10, +10, +23, and +30° C. were measured in addition to these experiments. After reaching the desired temperature in the chamber, the cells were tested after an additional 45 minutes to let the internal temperature of the cell reach the desired temperature. The experiments were performed during a single cycle and there was a small drop after each EIS. Control EIS measurements were performed with the same number of experiments and timing to ensure that these OCV drops do not contribute to a significant change in the measured impedance spectra. FIG. 5 shows the result of these experiments and the repeatability of the EIS experiments for cell CE. The same procedure was performed on the other cells.

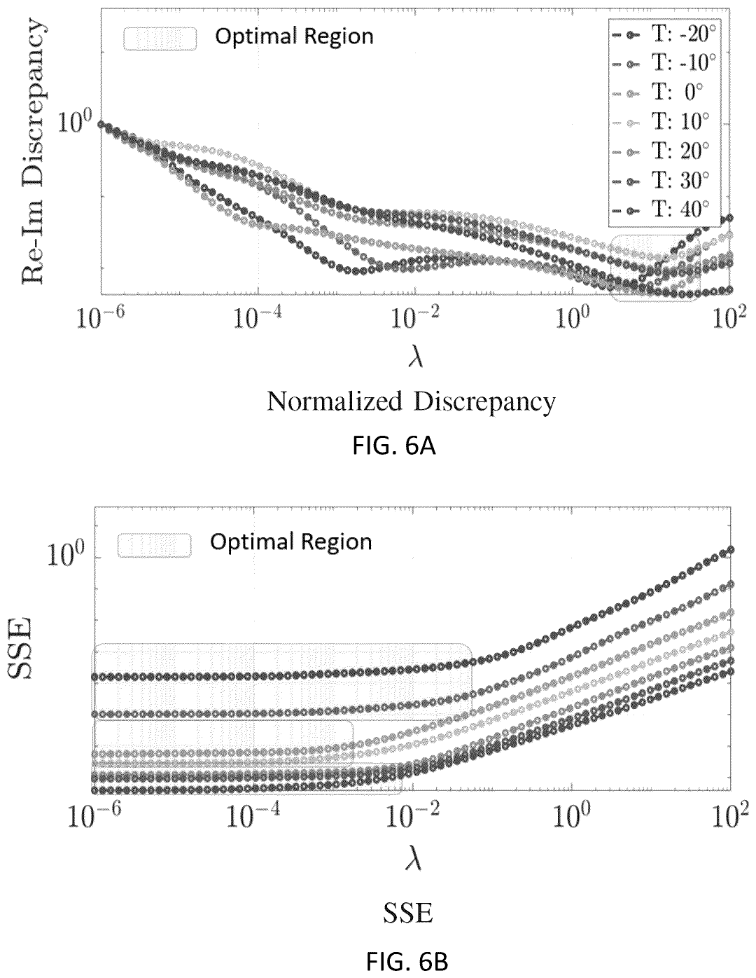

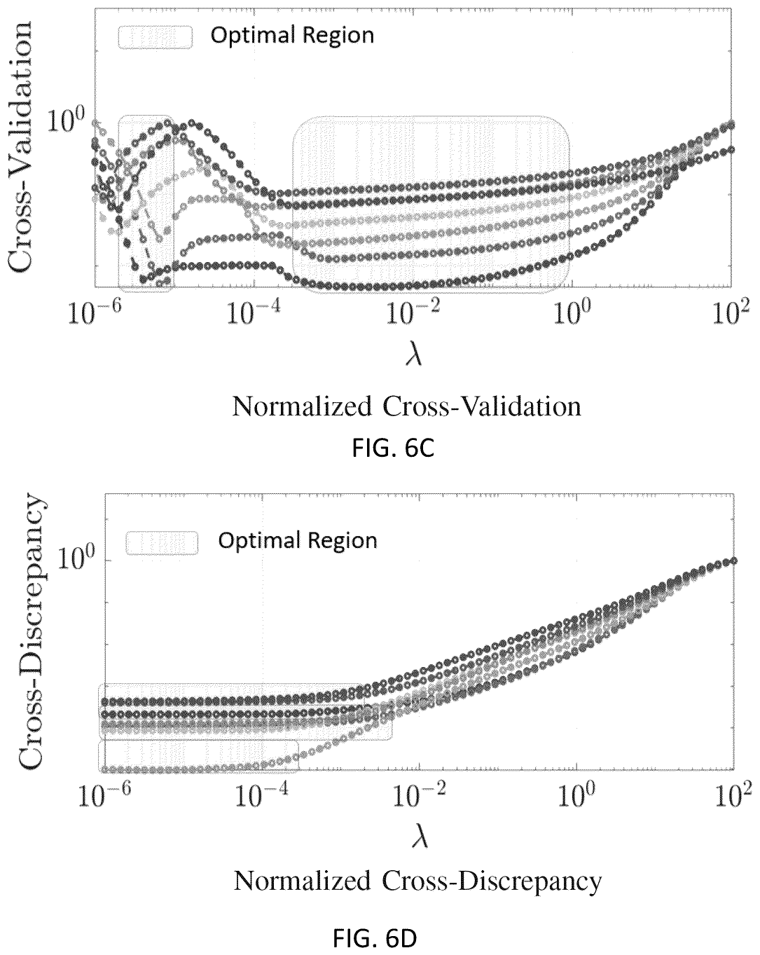

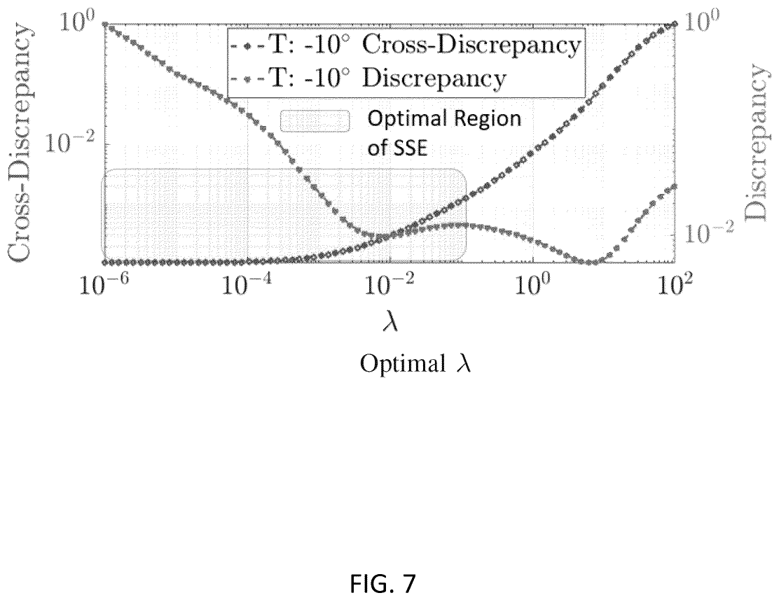

FIGS. 6A through 6D show the normalized versions of different cost functions given in Equations 12 through Equation 15 for the discharged cell CE (0% SOC) at different temperatures (T=−20, −10, 0, +10+20, +30 and +40° C.). The temperatures can be distinguished with the hue of the colors with dark blue for the coldest temperature (−20° C.), and dark red for the highest temperature (+40° C.). The same color-coding was used in FIGS. 8A-F. FIG. 6A suggests that larger values of λ would result in smaller Re-Im Discrepancy for all temperatures. Moreover, the DRT with larger λ has fewer peaks and larger fitting errors (SSE) as is evident in FIG. 6B. FIG. 6C shows the Re-Im Cross-Validation objective function and suggests small values of λ(<10⁻⁴) for all temperatures. However, using these values resulted in many oscillations and artificial peaks in DRT. FIG. 6D shows the Cross-Discrepancy cost function, and it plateaus at λ≈10⁻², which is consistent with the behavior of SSE. One can use larger values of λ before a significant increase in SSE. FIG. 7 shows the process of choosing the optimal regularization parameter with respect to three criteria of Discrepancy, Cross-Discrepancy, and the SSE leads to λ=0.008 for T=−10° C.

Referring now to FIGS. 8A-8F, DRT temperature and SOC dependencies are shown. FIG. 8A shows cell CE EIS, FIG. 8C shows RC elements DRT, and FIG. 8E shows RL elements DRT with 0% SOC at T=−20° C. to T=+40° C. FIG. 8B shows cell CE EIS, FIG. 8D shows RC elements DRT, and FIG. 8F shows RL elements DRT with 100% SOC at T=−20° C. to T=+40° C.. EIS measurements were conducted on cell CE at seven temperatures from −20C to +40C in 0% SOC and 100% SOC, as shown in FIGS. 8A-8B. The weighted sum of square errors, χ², also shows a good fit and for CE at 0% SOC and were computed as: χ²=10⁻⁴×[1.6,1.4,0.7,1.6,2.3,3.9,3.9] and for 100% SOC were computed as: χ²=10⁻⁴×[4.7,0.9,0.8,1.0,1.1,1.7,1.7] for T=[−20,−10,0,10,20,30,40]° C., respectively. Similar trend in the values of the cost-functions for all cells at 0% and 100% SOC at different temperatures were observed. The weighted sum of square errors for CF were computed as: χ²=10⁻⁴×[2.2,8.5,1.5,2.3] and for CH were computed as: χ²=10⁻⁴×[1.9,2.3,7.8,3.0] for T=[−20,0,20,40]° C., respectively.

These diagrams (FIGS. 8A-8B) show that the cell exhibits three different behaviors in high-, medium-, and low-frequency regions. Each of these figures shows the dependency of EIS on temperature with different colors: from dark blue to dark red for −20° C. to +40° C., respectively. The figures show that the EIS diagrams expand as the temperature decreases. Comparison of FIGS. 8A-8B shows that the EIS changes with SOC. For example, at 20° C. the slope on the right side of the figure becomes steeper at 100% SOC) (63° compared with the one at 0% SOC) (51°, which shows a more limited diffusion length and reflective boundary. The tail on the left side of the EIS diagram (mostly below the real axis) will be referred to as the high-frequency range. The intercept of the high-frequency range with the real axis is related to the Ohmic resistance of the cell and was increased as the temperature dropped. The medium-frequency region is the section that resembles a depressed semicircle and is expanded with the colder temperatures. The low-frequency region is the inclined line on the right side of the graph. The criteria of the previous section were used to find the DRT of this cell under the specified conditions. These peaks and their variations with SOC and temperature are shown in FIGS. 8A-8F. The DRT analysis resulted in four to five dominant peaks depending on the temperature. The low- to medium-frequency peaks (t=0:0001 to 100 s) are denoted by P_{S}, P_{C}, and P_{D}, as shown in FIGS. 8C-8D. Peaks P_{S}, P_{C}, and P_{D} are found using the distributed time constants associated with the RC elements in FIG. 2B. Note that the low-frequency region (shown as green, P_{D}) has two to three peaks, which are related to the diffusion process. The third peak disappears when the P_{C} peak moves to the right at lower temperatures. The RL DRT analysis resulted in one peak, P_{H} at very high frequencies (τ<1e−5), as shown in FIGS. 8E-8F. This peak is defined by the RL elements in FIG. 2B. P_{S}, P_{C}, and P_{D} are highly temperature dependent and, by reducing the temperature, their heights increase significantly. Furthermore, their temperature dependency does not change as the SOC changes from 0% to 100% SOC. Comparing the peak heights in FIG. 8C with the corresponding peak heights in FIG. 8D shows that P_{C} and P_{D} are more SOC dependent than P_{S}. This SOC dependency is more evident at lower temperatures; for example, at T=−20° C., the height of PD increases from 523.33 at 0% SOC to 617.37 mΩ at 100% SOC (17.98%) for P_{D}; whereas the changes in the height of P_{S} is less than 2% (16.44-16.73 mΩ).

The shift in the DRT peak frequencies and their heights when compared at different temperatures and SOC levels shows the nature of the electrochemical process of the peak. Assigning the internal processes to the DRT peaks involves checking the dependency of the peaks on temperature and SOC (see FIG. 1A). Some of these processes, such as diffusion, charge transfer, and SEI, have strong temperature dependencies, and some of them, such as the charge transfer, have strong SOC dependencies. Such dependencies were used combined with the expected range of time constants to assign the DRT peaks. The dominant mechanisms in LIBs are electron migration and electrolyte conductivity, SEI/CEI, charge transfer and double layer effects, solid and liquid diffusion, and Li-ion intercalation. The time constants of transport/interphase and reaction effects, such as SEI and charge transfer, are in the order of milliseconds. In contrast, the time constants of diffusion and intercalation effects are in seconds to hours. The impedance spectra used was collected from 0.01 Hz to about 47 kHz. It was expected to observe four to five peaks related to diffusion, charge transfer, and SEI in the DRT analysis considering this range since graphite/LiFePO₄ cylindrical cells have a diffusion time constant of about more than 1 s, and their SEI and charge transfer time constants are in the range of 0.0001-1 s (see Illig, J., Schmidt, J., Weiss, M., Weber, A., andlvers-Tiffe'e, E. (2013). Understanding the impedance spectrum of 18650 LiFePO₄-cells. J. Power Sources 239, 670-679. https://doi.org/10.1016/j.jpowsour.2012.12.020) (see Manikandan, B., Ramar, V., Yap, C., and Balaya,P. (2017). Investigation of physico-chemical processes in lithium-ion batteries by deconvolution of electrochemical impedance spectra. J. Power Sources 361, 300-309. https://doi.org/10.1016/j.jpowsour.2017.07.006). Another peak that was looked into in this study is associated with higher frequencies (>104 Hz). This response is shown by peak PH and modeled using an inductor in series with several RL elements. The dominant processes in this frequency range are related to the ionic conduction through the electrolyte and porous separator and contact resistances to the current collectors. Note that the inductive and resistive contributions of the wires were subtracted from the total measured impedance spectra, and this parameter is more dominant at a higher frequency range. Therefore, the changes in this high-frequency range (10-47 kHz) are related to the porous properties of the electrodes and separator.

Since P_{C} and P_{D} are temperature and SOC dependent, they are mostly associated with charge transfer and diffusion. Their associated dominant frequencies also confirm that their representative time constants are related to the charge transfer and diffusion, respectively. Note that the diffusion results in multiple peaks (see Boukamp, B. A. (2020). Distribution (function) of relaxation times, successor to complex nonlinear least squares analysis of electrochemical impedance spectroscopy? J. Phys. Energy 2, 042001. https://doi.org/10.1088/2515-7655/aba9e0) with an approximation relation of the first two peaks being

$$\frac{log ( 3 )}{log ( {τ}_{1} / {τ}_{2} )} = n \leq 0.5$$

On the other hand, P_{S} is temperature dependent, but it has a weak SOC dependency. Therefore, considering the experiments performed on the new cells, this peak is associated with the SEI layer dynamics. Unlike P_{S}, P_{C}, and P_{D}, the time constant of the PH remains almost constant at different temperatures and SOC. Also, its height increases moderately by increasing the temperature. A similar trend of changes in EIS and consequently a similar number of dominant peaks (with similar locations) in DRT have been observed for cell CF and CH which shows the effectiveness of the disclosed method for other cells. By assigning SEI, charge transfer, diffusion, and inductive-resistance mechanisms to the time constants of P_{S}, P_{C}, P_{D}, and PH, respectively, the effect of mechanical damage on these peaks are studied and detailed below.

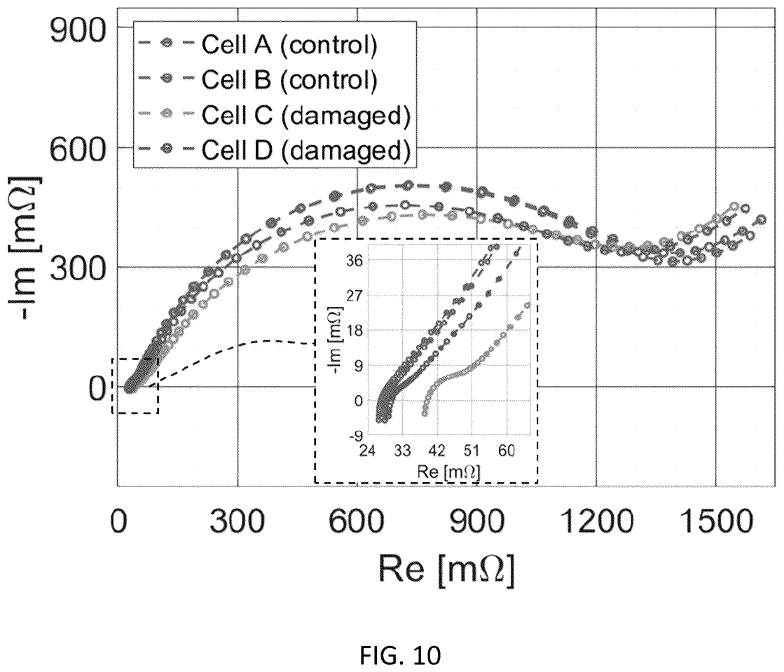

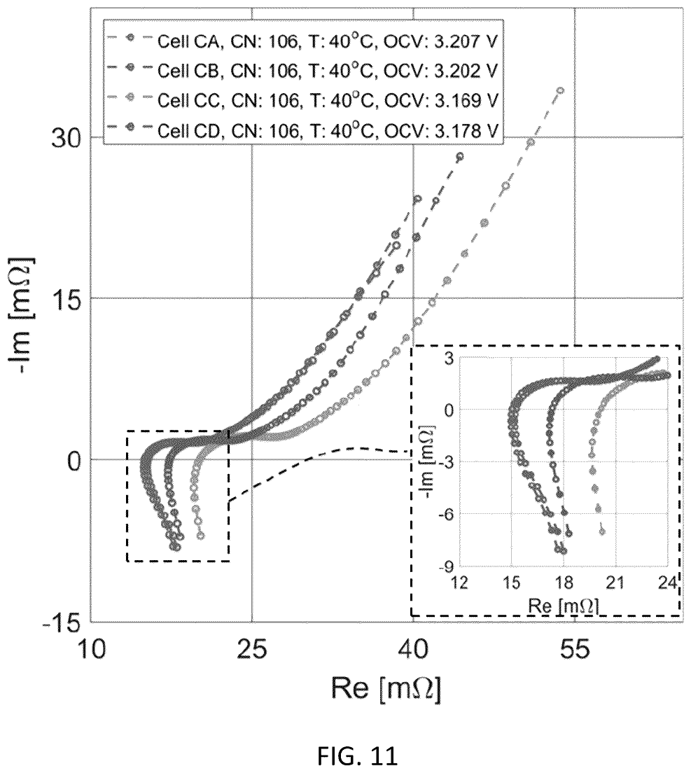

FIGS. 9-11 are plots showing additional exemplary experimental results. FIG. 9 shows impedance spectra of two damaged cells and two intact cells at room temperature (22° C.). FIG. 10 shows impedance spectra of two damaged cells and two intact cells at a low temperature (−20° C.). FIG. 11 shows impedance spectra pf two damaged cells and two intact cells at a high temperature (40° C.).

### DRT of Control and Damaged Cells

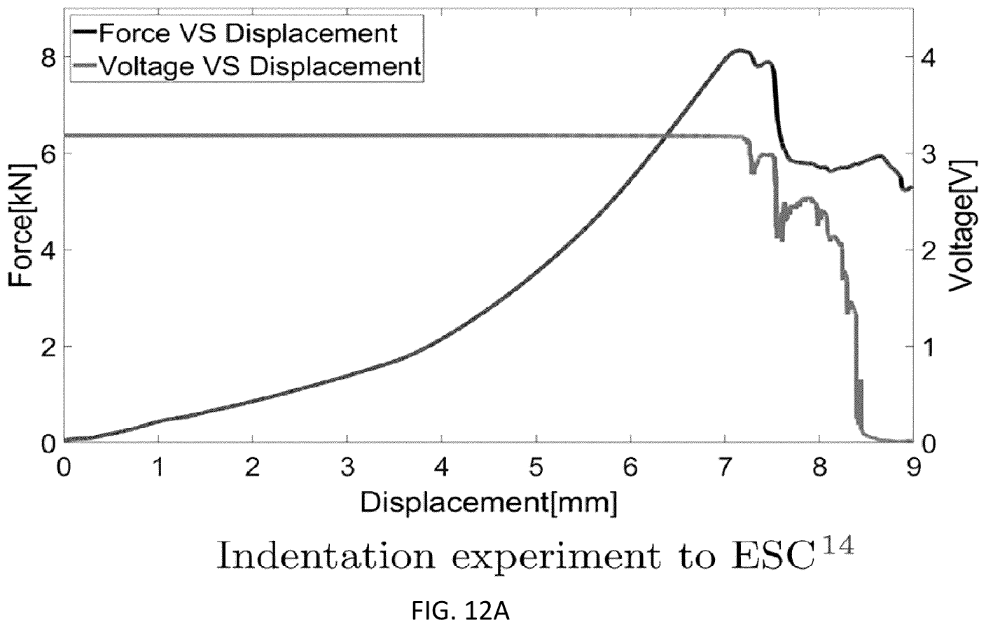

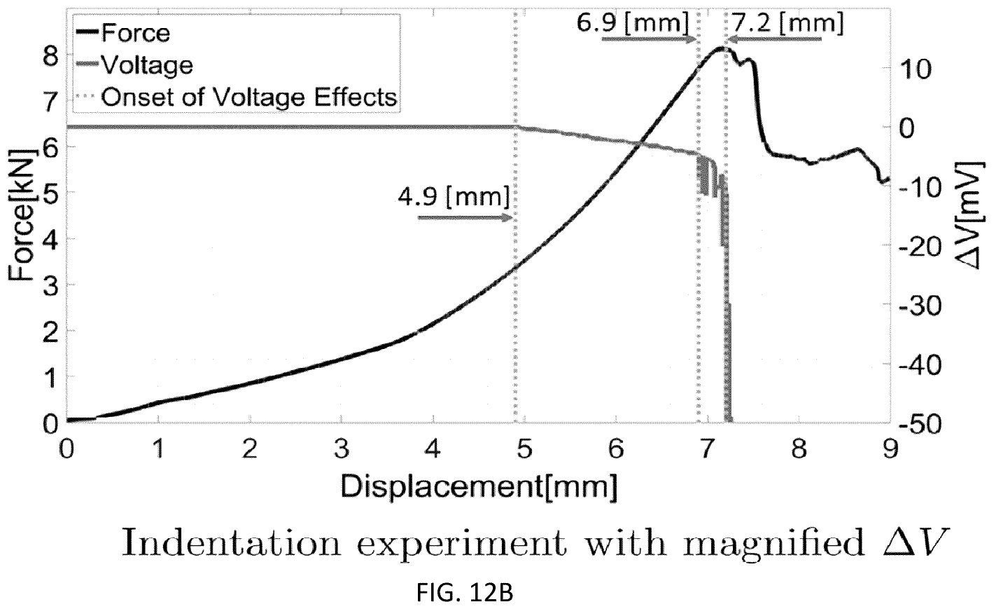

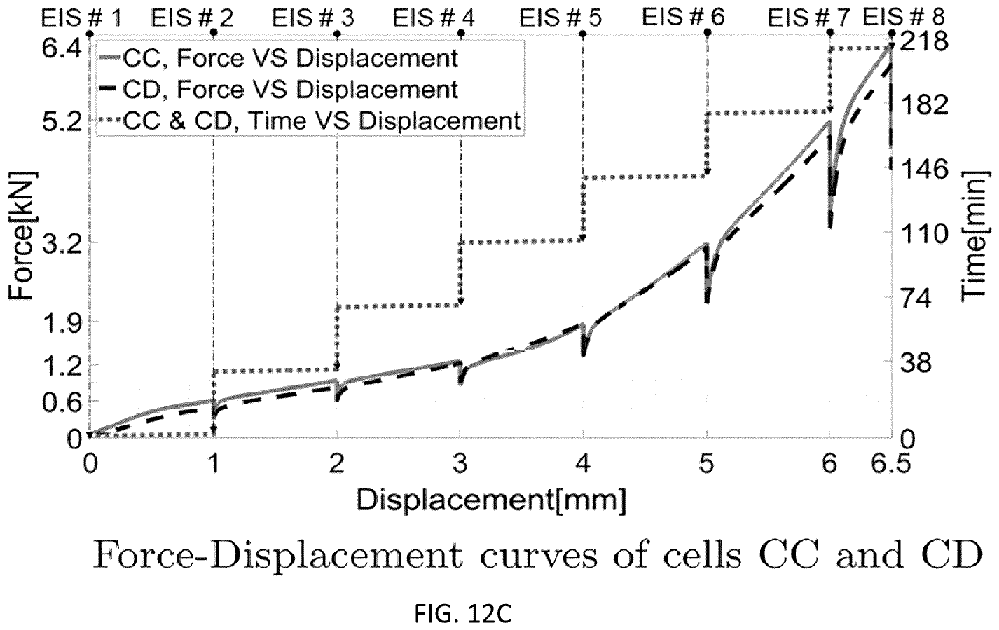

Here, the comparisons of the DRT peaks of two control cells versus two mechanically damaged cells are presented. Referring now to FIGS. 12A-12C, the results of force/voltage versus displacement in the indentation experiments are shown, with FIG. 12A showing curves from indenting a cell up to the electrical short circuit (ESC), FIG. 12B showing magnifying the voltage drop, which shows that the drop started around 5 mm, as suggested by the DRT analysis, and FIG. 12C showing cell CC and CD force displacement and time displacement (to collect the EIS data) of each step during cell indentation up to 6.5 mm.

The cells' capacity were measured at the beginning of the experiments as 1.3245, 1.3426, 1.3076, and 1.2996 Ah (M=1.3186, SD=0.0165) for cells CA, CB, CC, and CD, respectively. Also, the cells had Coulombic efficiencies of 0.9953, 0.9963, 0.9968, and 0.9976 (M=0.9965, SD=0.0008), respectively. FIG. 12C shows the force-displacement curves of the CC and CD cells during the seven-step loading; the two curves are almost identical, verifying the repeatability of the experiments. The tests involved six 1 mm displacement loadings, followed by a 0.5 mm displacement loading. The maximum displacement of 6.5 mm was selected because previous studies have shown that the cells would have a considerable OCV drop after 6.9 mm of deformation before the force-displacement reaches its peak at 7.2 mm (see FIG. 12A).

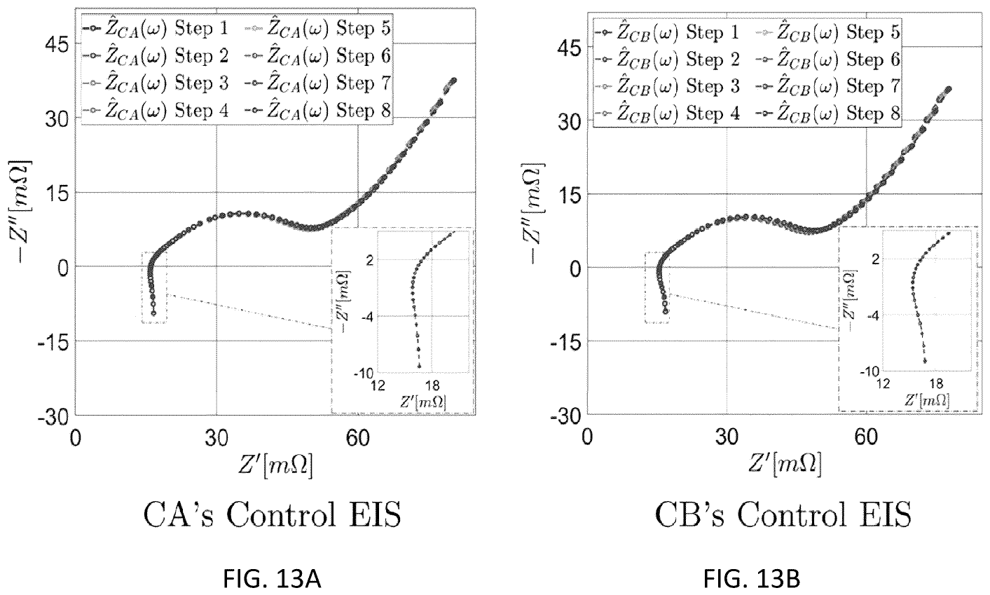

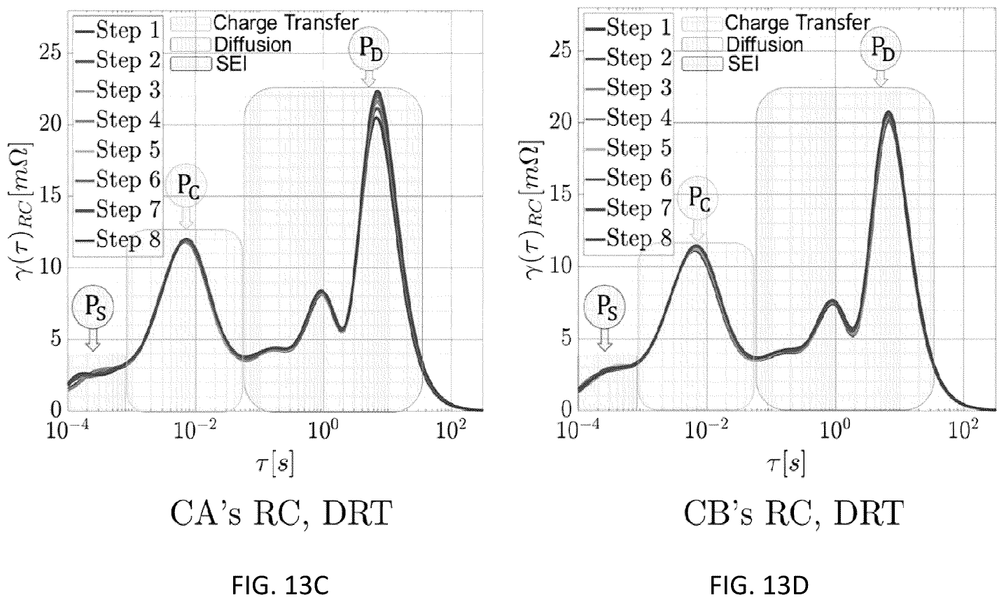

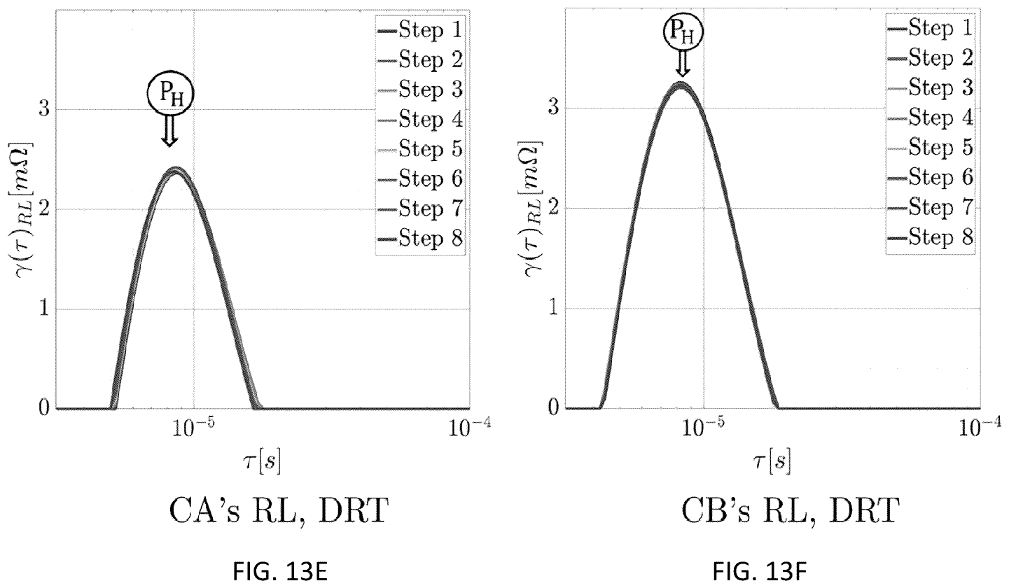

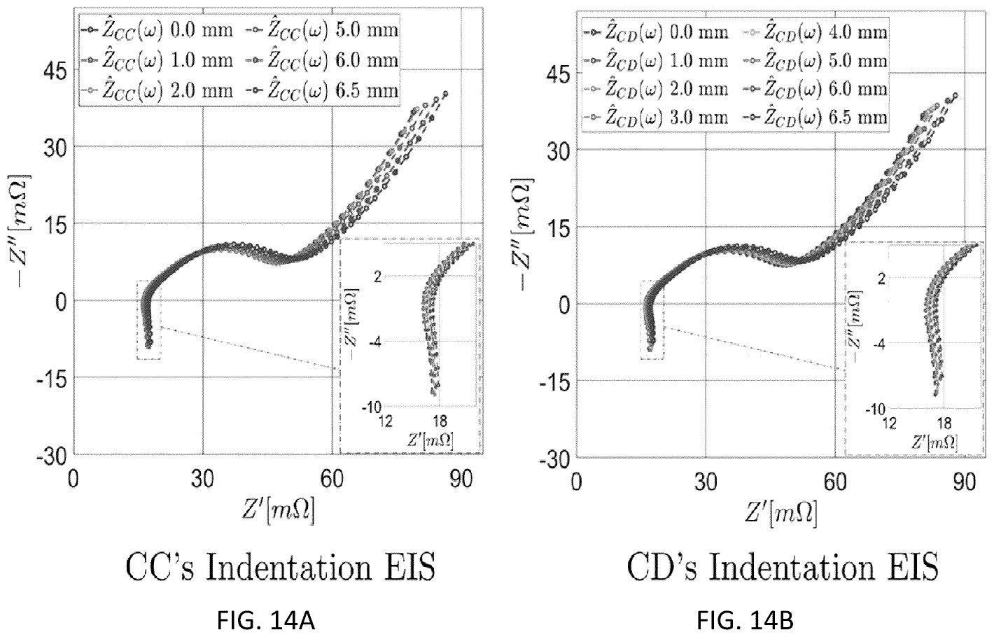

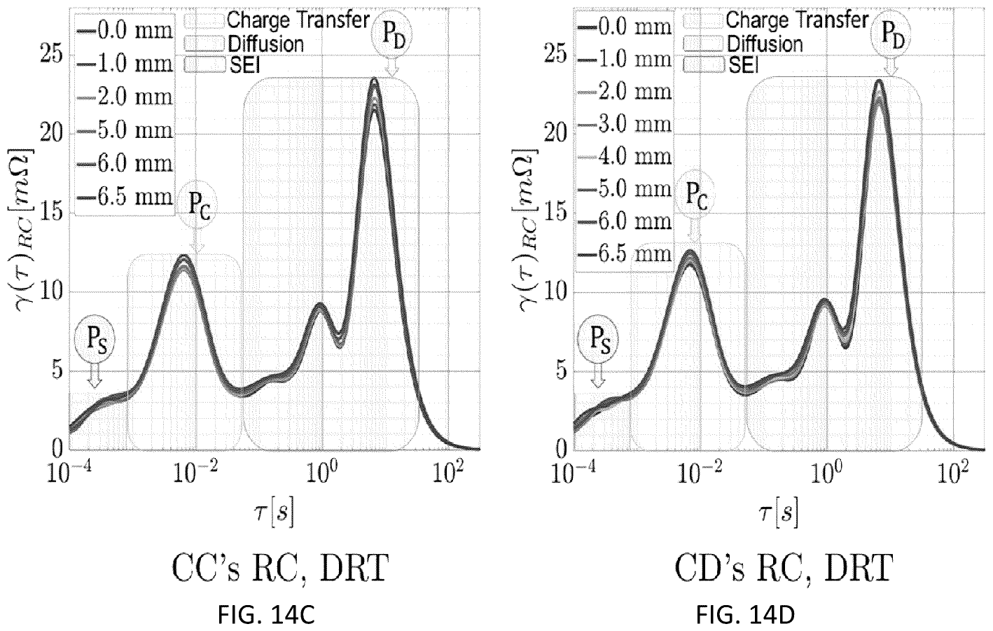

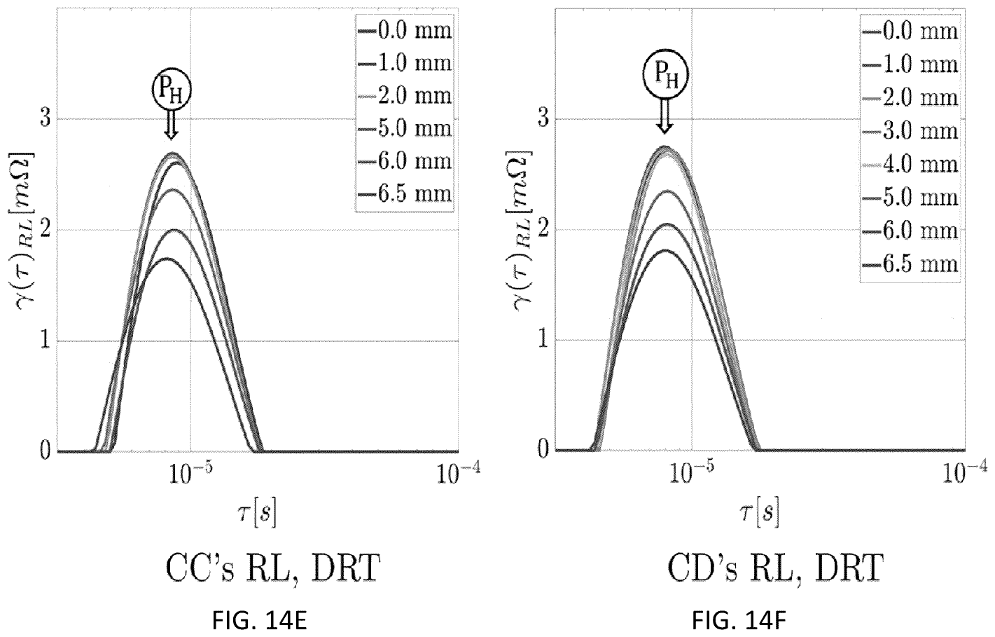

EIS and the related RC and RL element DRTs of control cells CA and CB are shown in FIGS. 13A-13F, where DRT of control cells is shown at room temperature. FIGS. 13A-13B show Cell CA and CB control EIS, respectively. FIGS. 13C-13D show RC elements DRTs, respectively. FIGS. 13E-13F show RL elements DRTs, respectively, at 0% SOC and T=+23C. The EIS steps are shown with the color hue dark blue for the first step to dark red for the last step. The same color coding was used in FIGS. 14A-14F for corresponding indentation steps of CC and CD cells from 0 to 6.5 mm. Note a small drop in the OCV of the indented cells after each EIS step. The OCV drop of the control cells was about 2-3 mV after each test. At room temperature, the total drop from the first step to the last (eighth) was about 25 mV for 0% SOC. The OCV drops of the cells after each EIS at indentation experiments were in the same range as the control experiments and the total changes in OCVs were about 17 mV. The studies on the control cells show that the OCV drop did not significantly contribute to the changes in EIS diagrams. FIGS. 13A-13B show almost identical EIS diagrams in the control group as they were tested eight times, resulting in almost identical low- and medium-frequency peaks (P_{C} and P_{D}) of the steps as shown in FIGS. 13C-13D. Furthermore, the high-frequency peaks P_{S} and PH remain unchanged, as shown in FIGS. 13C-13F. These results show that the effect of time and the OCV drops after each EIS of the control group cells (about 25 mV total drop in OCV) do not affect the results. Therefore, any changes observed in the mechanically damaged cells can be attributed to the extent of the mechanical damage.

Note that the temperature and SOC were kept constant during these EIS steps; therefore, the passage of time (3.5 h) and drop in OCV (about 25 mV) are the main variables in the control experiment that can affect the EIS. Thus, the timing of the experiment's steps and the OCV drop for both types of experiments (control EIS and indentation) are identical, as shown in FIGS. 13A-13F.

EIS of the mechanically damaged cells (CC and CD) and the related RC and RL element DRTs are shown in FIGS. 14A-14F. FIGS. 14A-14F show DRT of damaged cells at room temperature. FIGS. 14A-14B show Cell CC and CD's indentation EIS, respectively. FIGS. 14C-14D show RC elements DRTs, respectively. FIGS. 14E-14F show RL elements DRTs, respectively, at 0% SOC and T=+23C. Apparent changes in EIS diagrams can be observed when increasing the mechanical indentation from 0 to 6.5 mm in FIGS. 14A-14B. The zoomed-in figure shows the intersection of the EIS diagram, and the real axis increased with the extent of the indentation. This intersection is closely related to the ohmic resistance of the cell. The high-frequency tail of the impedance shows another critical trend in the slope (shape) of the tail as the mechanical displacements increase. Changes were observed in the DRT peak of the RL elements, PH, in FIGS. 14E-14F, where the height of the peak decreases significantly by increasing the indentation, while the frequency of PH almost remains unchanged. FIGS. 14C-14D show that the height of Pc and P_{D} do not change significantly during the mechanical indentation.

### DRT Peak Analysis

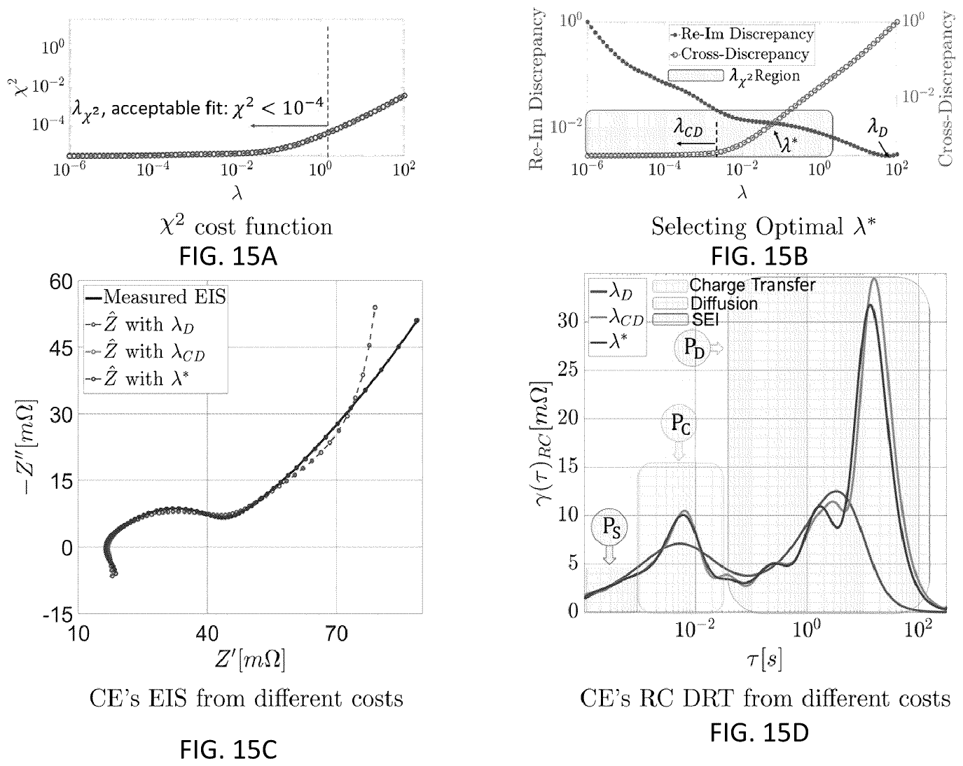

Referring now to FIGS. 15A-15D, trade-off in picking optimal λ* is shown with criteria to determine λ* for T=+20C, cell CE, (FIG. 15A) χ² versus λ, (FIG. 15B) discrepancy and cross-discrepancy versus λ, (FIG. 15C) the measured and reconstructed EIS, and (FIG. 15D) RC DRT with optimal λ form different cost functions (λ_{D}, λ_{CD}, and λ*).

This section analyzes the DRT results using each peak's representative time constant and height. FIGS. 15A-15D shows the criteria to determine λ* for cell CE at T=+20C and their impact on the number of peaks and the reconstructed EIS. FIG. 15A shows the weighted error decreases with smaller λ and plateaus with λ<1. FIG. 15B shows that the Re-Im discrepancy cost (blue line) decreases as λ increases; therefore, using only this cost, the optimal λ* would be >10². Therefore, these common choices of cost functions result in conflicting values for the regularization parameter, λ*. The additional disclosed cost function, cross-discrepancy cost (orange line), is also shown in FIG. 15B. This cost increases with λ>10⁻³. Using a combination of these cost functions, λ*=0.07 was chosen, as shown in FIG. 15B. FIGS. 15C-15D show the effect of the regularization parameter. As shown in FIG. 15C, the discrepancy cost function resulted in very large errors in the reconstructed EIS. FIG. 15D shows that the λ* suggested by the intersection of the cross-discrepancy and discrepancy meets the requirement χ²<10⁻⁴ (good fit) and offers a trade-off between the smooth curves and too many peaks.

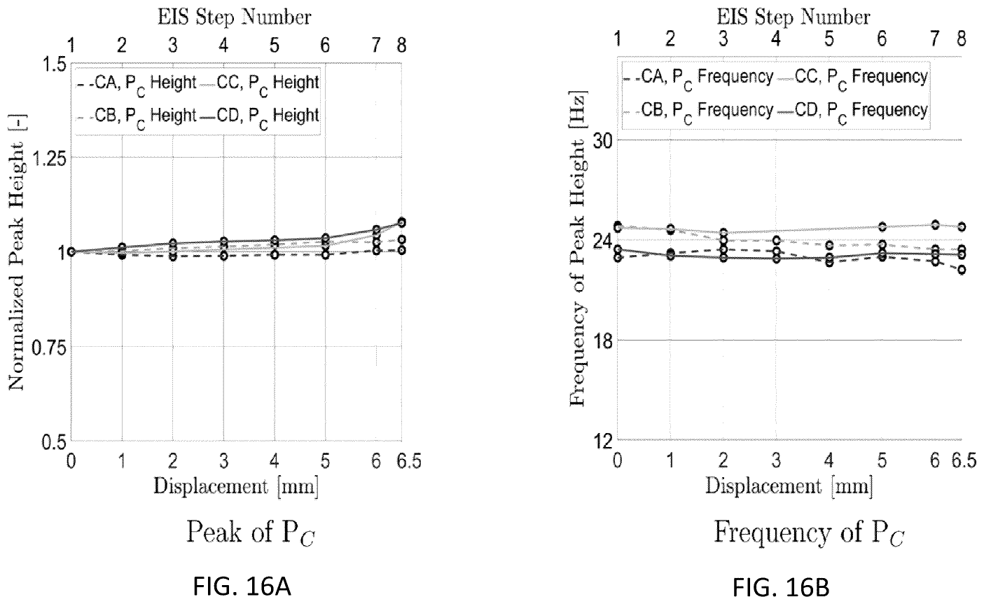

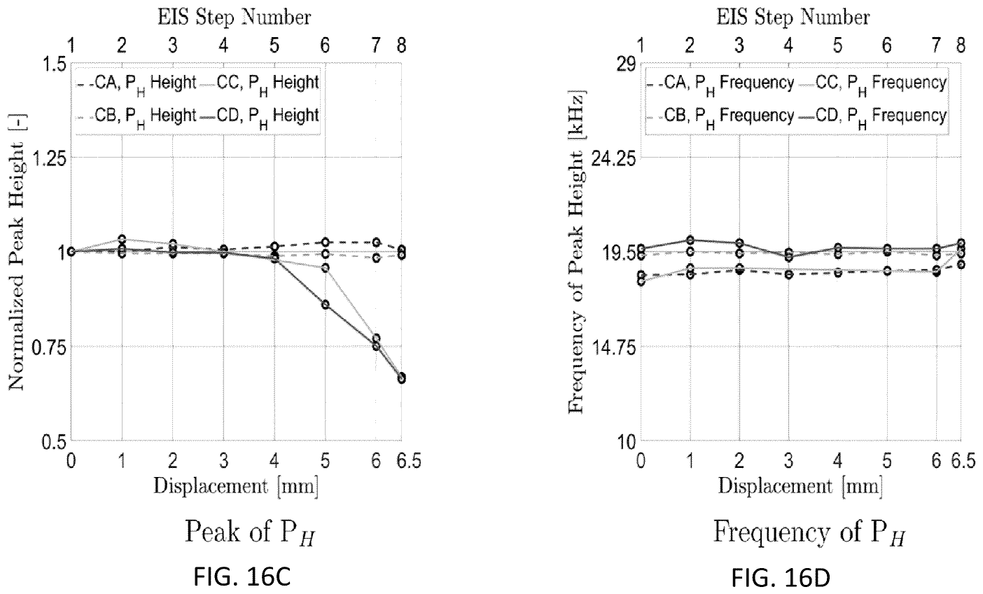

To better visualize the changes in the heights of the peaks, the heights were normalized using the height of the first step for each cell. The trend of the peaks of the DRT outputs for P_{C} and P_{H} in control and indentation experiments are shown in FIGS. 16A-16D, where FIG. 16A shows height of PC (charge transfer), FIG. 16B shows frequency of PC, FIG. 16C shows height of PH (RL elements), and FIG. 16D shows frequency of PH. By analyzing the height and frequencies of the peaks in FIGS. 13-14, one can see that the frequencies of all four peaks remain almost constant during control and indentation experiments, which implies that the mechanical damage does not significantly affect the time constants of the peaks (as an example, see FIG. 16B). Peak analysis shows that the heights of P_{S}, P_{C}, and P_{D} do not change much with the mechanical indentation (as an example, see FIG. 16A). The average changes in the height of P_{C} in control and indentation experiments are 2:4% and 8:1%, respectively, and for P_{D} in control and indentation, experiments are 5:5% and 7:6%. It can be identified that the changes in the height of peaks P_{C} and P_{D} in control and indentation experiments are close to each other, which means that mechanical damage has a negligible effect on charge transfer and diffusion, which are assigned to P_{C} and P_{D}. Similarly, the changes in P_{S} heights were in the same order in both control and mechanical indentation experiments. However, it was observed that there is a more direct effect of the indentation on the height of P_{H} as shown in FIG. 16C. The frequency of this peak does not change much with the mechanical indentation, as shown in FIG. 16D. The height of P_{H} changes significantly (≈36: 0% at 6.5 mm displacement) for the indented cells compared with just 2: 5% for the control experiments.

It was observed that the PH height reduction starts at a deformation of about 5 mm and then continues to drop consistently as the displacement increases to the maximum value of 6.5 mm. An investigation was performed to verify how this observation can be related to the electrochemical damage in the cell. As discussed previously, the maximum deformation of 6.5 mm was chosen per previous mechanical crush for short electrical experiments. In those experiments, no EIS was taken, and no interruption was made in the cell deformation until reaching a hard short circuit and total cell failure (see FIG. 12A). In those experiments, the cell voltage remains almost constant at 3.18 V until 6.9 mm deformation, where a region of unstable voltage oscillations with a magnitude of 4 mV starts. Then, a major voltage drop was observed at the peak force at 7.2 mm deformation in the magnitude of ≈0:38 V.

A more careful look at the voltage profile shows that the point of 5 mm deformation where the P_{H} starts to change can be correlated with sub-mV level changes in voltage in that cell. A zoomed-in change in voltage is shown for the mechanically tested cell (where no EIS was taken) at mV levels (see FIG. 12B). It was interesting to observe that the voltage had remained completely constant up to the precision of the measurement with four significant digits (3.1799 V) until 4.9 mm deformation. A gradual decrease in voltage in the order of 0.1 mV per 0.01 mm deformation starts at this point and continues until 6.9 mm, where the voltage drops more rapidly (4 mV oscillations). This indicates that electrochemical damage in the cell started at 4.9 mm, which was detected by a distinct change in the peak PH from the DRT analysis at 5 mm. It should be noted that mere taking of EIS at one step causes a voltage drop of about 2-3 mV in the cell. Therefore, unless the cell damage is visually inspected, simply a 0.1 mV drop in voltage cannot be used as an indication of mechanical deformation. This observation highlights the significance of PH in detecting damage in the cell. PH was able to detect the physical change in the cell at 5 mm damage, where P_{S}, P_{C}, and P_{D} remain constant and not affected. Note that P_{H} is not merely measuring this 0.1 mV drop in voltage because in the control group cells, repeating the EIS eight times, which causes about a 20 mV drop in voltage, had not affected the value of PH. Instead, PH detects the mechanical damage that is independently evident in the crush to short cell experiment with the 0.1 mV drops in voltage. This peak is related to the contact resistances and ionic conductivity through the electrolyte and separator pores. A more careful review of the equations shows that R_{RL} and L_{RL} parameters affect this peak. First, notice that the time constant of P_{H} remains almost constant, suggesting that the ratio L_{RL}=R_{RL} does not change; however, the magnitude decreases, which implies that the conductivity is increased as the mechanical deformation increased (R_{RL} decreases). This combined effect suggests that the electrodes are compressed and permanently become more compact with the mechanical indentation. This is an expected outcome and shows that the proposed DRT approach successfully determines the source of changes in the EIS results.

### DISCUSSION

In this section, three critical implications of this research are discussed. The first point of discussion is how the method can quantify cell safety. This can be achieved by decoupling the effects of various interacting environmental and cell conditions, such as temperature, SOC, and mechanical damage. The second point is the real-world applications and scenarios in which the method can be applied effectively. This research aimed to provide a non-invasive tool to detect the safety of a battery used under real-world conditions and subjected to mechanical overloading. These potential abusive scenarios are unavoidable when batteries are used in vehicular applications, such as impact and crashes due to road accidents of EVs or landing shocks and acceleration pulses in drones. When the cells are located in modules and battery packs and heavily protected by rigid types of exterior casings and vehicle structures designed to ensure zero deformation, the crash pulse from the accident may directly transfer to the pack's interior. Inertial loads can still damage the cells or connections inside the packs without any external indications of deformation. On the other hand, if a crash leads to minor damage to the casing, it may not be possible to predict whether this external observation has reached the point of damaging the cells inside the pack or it is only a cosmetic imperfection. This potential hazard forces significant overdesign of protective structures and a conservative approach of throwing out any pack with minor cosmetic damages. In addition, note that both the current work, as well as past research of the authors, all confirm that the cell voltage can remain highly stable throughout considerable amounts of deformation. Therefore, mechanical damage cannot be readily detected by simply measuring the cell's voltage before and after the accidental overloading, and there is an urgent need to invent a tool to detect damage from electrical measurements without needing to open the pack in every scenario. This research provided the first fundamental strides to reach that goal. The steps in evaluating safety in such cases using the current method would include (1) taking a reference EIS from the cell when in its initial condition before it has been subjected to any loads (reference EIS), (2) taking another EIS from the cell after it has been subjected to the accidental load (evaluation EIS), and (3) conduct DRT analysis to find the peaks and use criteria for the extent of changes in these values to mark the cell damaged or undamaged. It is essential to have reference EIS and evaluation EIS in the same SOC and temperature to avoid variations due to the changes in SOC and temperature. Also, the criteria utilize the normalized parameters of each cell rather than the nominal values to bypass cell-to-cell variations. Therefore, the cells are compared with themselves before and after the event, not to other cells.

Now, it is important to propose how practically the above conditions can be met in applying this method in a real-world application. Here, it is proposed for three types of applications, (1) use in EV evaluation during standard crash tests, (2) use in planned impact and shock applications, and (3) use as a regular safety check-up. In the first proposed use, the method can evaluate if the battery pack in an electric vehicle that has undergone a crash test has survived the experiment. This application would benefit the car manufacturers, NHTSA (National Highway Traffic Safety Administration), and IIHS (the Insurance Institute for Highway Safety) for developing standards and ratings such as FMVSS (Federal Motor Vehicle Safety Standards), NCAP (New Car Assessment Program), or IIHS types of safety tests. Usually, in such crash tests, the batteries are discharged before the test, and they do not get disassembled for any visual checks after the test, so it remains practically unknown whether the cells have been damaged inside the battery pack unless there is a major change in voltage. The current approach can be used in the above tests by conducting an EIS and DRT analysis right before the crash test at room temperature and after the crash test is completed, in the same SOC and temperature. The second application would be in cases of EV crashes, drone landings, or the defense use of batteries; in such cases, the EIS should be measured in situ when the threat of impact is imminent. This would be done when the airbag sensor gets activated or when the landing decision is made and then after the completion of that incident. These events are so short in duration that no major change in SOC is expected. The only matter to ensure is that post-event evaluation EIS should be taken at the same temperature detected during the reference EIS. It should be noted that, due to the short time available in these cases, measuring the entire EIS range would not be possible; however, the PH analysis only requires measuring impedance spectra at frequencies larger than 104 Hz. For reference, an airbag sensor triggers at 50 ms. The third application could be a regular check: an EV owner may keep the test equipment in their garage and test the battery by taking an evaluation EIS every morning when it is at 100% SOC at room temperature before leaving their garage, and then every day make a comparison with the reference EIS from the day before.

### Experimental Setup and Data Collection

Several experiments were conducted on seven 18650 cylindrical Lithium-ion cells to generate the data for the DRT analysis. The cells had graphite anodes and Lithium Iron Phosphate (LiFePO₄) cathodes. The nominal capacity of the cells at C/5 is 1.5 Ah, and the recommended cutoff charge and discharge voltages were 3.65 and 2.5 V, respectively. The recommended operating temperature of the cells was from −20° C. to +60° C.

All cells underwent the beginning of life (BOL) characterization, where they were charged and discharged with a C/10 rate five times. The charge cutoff voltage was set to 3.65 V, and the discharge cutoff voltage was set to 2.5 V for these experiments. The impedance spectra were measured at a frequency range of 10 mHz to 47 kHz after each discharge with a four-electrode EIS measurement. After the initial characterization of the cells, the cells went through 40 charge/discharge cycling at 1 C until stable cycle-to-cycle EIS measurements were established.

### Temperature and SOC Experiments

Three of the cells (Cell CE, CF and CH) were used to investigate the effect of temperature and SOC on the EIS measurements and the resulting DRT peaks. Using these results, the peaks were assigned to the appropriate electrochemical processes. The charge and discharge cycling of the cell was conducted at room temperature (+23° C.) in a temperature chamber. Then, the chamber's temperature was set to the desired temperatures for EIS measurements. EIS measurements were conducted at these temperatures after the cell's external temperatures reached the desired temperature. The cell was left for an additional 45 minutes to ensure that the cell's internal temperature reached the desired temperature. The EIS experiments were conducted on cell CE at temperatures −20 to +40° C. in the MTI thermal test chamber at 0% and 100% SOC.

### Mechanical Damage Experiments

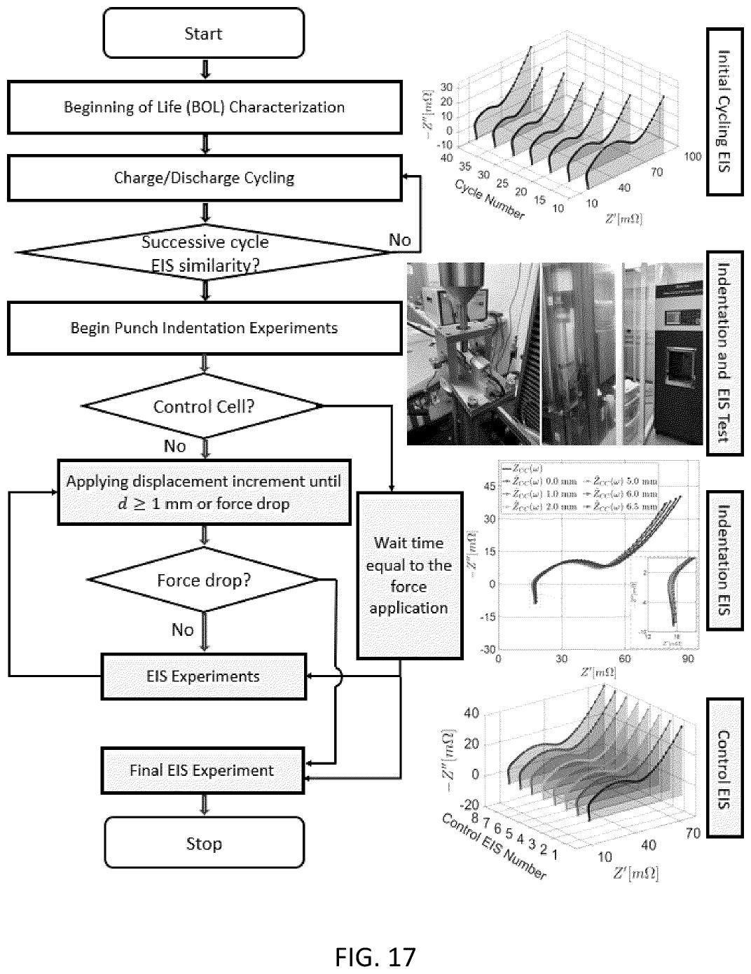

The remaining cells were divided into two groups. Cells CA and CB were used as control groups, while cells CC and CD were indented to study the effect of mechanical damage. These studies (including the indentation) were performed at room temperature (+23° C.) and 0% SOC (discharged) to ensure safety while applying indentations and measuring the electrical responses. A summary of the experiments is shown in FIG. 17. The indentations were applied by an Instron 5985 universal load frame using an in-house fixture. The fixture allowed measuring the voltage in real-time and conducting EIS experiments while the cell was under the load. A 12.7 mm hemispherical punch was used, which passed through the hole in the top part of the holding fixture (see FIG. 17). The indentor was attached to the moving part of the load frame, which had a velocity of 1 mm/min. The force, indentor displacement, and cell voltage were recorded during the mechanical loading. The loading (indentation) was held after each 1 mm displacement to measure the impedance spectra of the cell (in the last step, there is only 0.5 mm displacement). Each stop was timed 35 minutes, including a five-minute rest time after indentation, followed by EIS measurements, and a five-minute rest time before the next indentation step. The punch indentation was stopped after observing significant changes in the EIS measurements (and the parameters of a distributed equivalent circuit model). The total indentation of 6.5 mm was less than 7.2 mm, the indentation that would result in a hard short circuit and total failure of the cell. The total time to perform these experiments was about 3.5 hours. To account for the changes in the EIS measurements and decouple the effect of punch indentation from the order of the experiment and the OCV drops after each EIS measurement, similar EIS experiments were conducted on the control cells. Therefore, cells CA and CB were tested with the exact timing of the tests on two indented cells. These studies confirmed that the EIS measurements were repeatable, and the timing resulted in negligible changes in the impedance spectra compared to the changes due to the punch indentation.

### DRT Matrices

As discussed above, by adding new elements to Equation 21, one arrives at Equation 22. One can write the DRT formulation, Equation 22, in matrix form. This is achieved by manipulating (7) to separate the real and imaginary parts of the impedance and rearrange them in a matrix form as:

$$( X ) = {A}^{′} X + {R}_{∞} \qquad ( 27 )$$

$$( X ) = {A}^{″} X + j ω L + j \frac{1}{ω C} \qquad ( 28 )$$

where [symbol] and [symbol] are real and imaginary parts of reconstructed impedance, respectively. A′ and A″ are real and imaginary parts of summations in Equation 22 in the matrix form as given below:

$${[ {A}^{′} ]}_{N \times ( M + K )} = [ \begin{matrix}\frac{1}{1 + {( {ω}_{1} {τ}_{1} )}^{2}} & … & \frac{1}{1 + {( {ω}_{1} {τ}_{M} )}^{2}} & \frac{{( {ω}_{1} {τ}_{RL , 1} )}^{2}}{1 + {( {ω}_{1} {τ}_{RL , 1} )}^{2}} & … & \frac{{( {ω}_{1} {τ}_{RL , K} )}^{2}}{1 + {( {ω}_{1} {τ}_{RL , K} )}^{2}} \\ \frac{1}{1 + {( {ω}_{2} {τ}_{1} )}^{2}} & … & \frac{1}{1 + {( {ω}_{2} {τ}_{M} )}^{2}} & \frac{{( {ω}_{2} {τ}_{RL , 1} )}^{2}}{1 + {( {ω}_{2} {τ}_{RL , 1} )}^{2}} & … & \frac{{( {ω}_{2} {τ}_{RL , K} )}^{2}}{1 + {( {ω}_{2} {τ}_{RL , K} )}^{2}} \\ ⋮ & ⋮ & ⋮ & ⋮ & ⋮ & ⋮ \\ \frac{1}{1 + {( {ω}_{N} {τ}_{1} )}^{2}} & … & \frac{1}{1 + {( {ω}_{N} {τ}_{M} )}^{2}} & \frac{{( {ω}_{N} {τ}_{RL , 1} )}^{2}}{1 + {( {ω}_{N} {τ}_{RL , 1} )}^{2}} & … & \frac{{( {ω}_{N} {τ}_{RL , K} )}^{2}}{1 + {( {ω}_{N} {τ}_{RL , K} )}^{2}}\end{matrix} ] \qquad ( 29 )$$

$${[ {A}^{′} ]}_{N \times ( M + K )} = [ \begin{matrix}\frac{- {ω}_{1} {τ}_{1}}{1 + {( {ω}_{1} {τ}_{1} )}^{2}} & … & \frac{- {ω}_{1} {τ}_{M}}{1 + {( {ω}_{1} {τ}_{M} )}^{2}} & \frac{{ω}_{1} {τ}_{RL , 1}}{1 + {( {ω}_{1} {τ}_{RL , 1} )}^{2}} & … & \frac{{ω}_{1} {τ}_{RL , K}}{1 + {( {ω}_{1} {τ}_{RL , K} )}^{2}} \\ \frac{- {ω}_{2} {τ}_{1}}{1 + {( {ω}_{2} {τ}_{1} )}^{2}} & … & \frac{- {ω}_{2} {τ}_{M}}{1 + {( {ω}_{2} {τ}_{M} )}^{2}} & \frac{{ω}_{2} {τ}_{RL , 1}}{1 + {( {ω}_{2} {τ}_{RL , 1} )}^{2}} & … & \frac{{ω}_{2} {τ}_{RL , K}}{1 + {( {ω}_{2} {τ}_{RL , K} )}^{2}} \\ ⋮ & ⋮ & ⋮ & ⋮ & ⋮ & ⋮ \\ \frac{- {ω}_{N} {τ}_{1}}{1 + {( {ω}_{N} {τ}_{1} )}^{2}} & … & \frac{- {ω}_{N} {τ}_{M}}{1 + {( {ω}_{N} {τ}_{M} )}^{2}} & \frac{{ω}_{N} {τ}_{RL , 1}}{1 + {( {ω}_{N} {τ}_{RL , 1} )}^{2}} & … & \frac{{ω}_{N} {τ}_{RL , K}}{1 + {( {ω}_{N} {τ}_{RL , K} )}^{2}}\end{matrix} ] \qquad ( 30 )$$

### REFERENCES

The following publications are each hereby incorporated herein by reference in their entirety:
A. D. Franklin and H. J. De Bruin, “The Fourier analysis of impedance spectra for electroded solid electrolytes,” Phys. Stat. Sol. (a), vol. 75, no. 2, pp. 647-656, February 1983.
H. Schichlein, A. C. M. Ller, and M. Voigts, “Deconvolution of electrochemical impedance spectra for the identification of electrode reaction mechanisms in solid oxide fuel cells,” J. Appl. Electrochem., vol. 32, no. 8, pp. 875-882, 2002.
P. Agarwal and M. E. Orazem, “Measurement Models for Electrochemical Impedance Spectroscopy,” J. Electrochem. Soc., vol. 139, no. 7, p. 11, 1992.
B. A. Boukamp, “Distribution (function) of relaxation times, successor to complex nonlinear least squares analysis of electrochemical impedance spectroscopy?” J. Phys. Energy, vol. 2, no. 4, p. 042001, August 2020.
P. Buschel, U. Troltzsch, and O. Kanoun, “Calculation of the distribution of relaxation times for characterization of the dynamic battery behavior,” in Int. Multi-Conf. Syst. Signals Devices, Chemnitz, Germany, March 2012, pp. 1-3.
F. Ciucci and C. Chen, “Analysis of Electrochemical Impedance Spectroscopy Data Using the Distribution of Relaxation Times: A Bayesian and Hierarchical Bayesian Approach,” Electrochim. Acta, vol. 167, pp. 439-454, June 2015.
M. A. Danzer, “Generalized Distribution of Relaxation Times Analysis for the Characterization of Impedance Spectra,” Batteries, vol. 5, no. 3, p. 53, July 2019.
A. L. Gavrilyuk, D. A. Osinkin, and D. I. Bronin, “The use of Tikhonov regularization method for calculating the distribution function of relaxation times in impedance spectroscopy,” Russ J Electrochem, vol. 53, no. 6, pp. 575-588, June 2017.
M. Hahn, S. Schindler, L.-C. Triebs, and M. A. Danzer, “Optimized Process Parameters for a Reproducible Distribution of Relaxation Times Analysis of Electrochemical Systems,” Batteries, vol. 5, no. 2, p. 43, May 2019.
J. Illig, J. Schmidt, M. Weiss, A. Weber, and E. Ivers-Tiff′ee, “Understanding the impedance spectrum of 18650 LiFePO4-cells,” J. Power Sources, vol. 239, pp. 670-679, 2013.
J. Illig, “Physically based Impedance Modelling of Lithium-Ion Cells,” Ph.D. dissertation, Karlsruher Institut of Technology, April 2014.
K. Kobayashi and T. S. Suzuki, “Distribution of Relaxation Time Analysis for Non-ideal Immittance Spectrum: Discussion and Progress,” J. Phys. Soc. Jpn., vol. 87, no. 9, p. 094002, September 2018.
A. Leonide, V. Sonn, A. Weber, and E. Ivers-Tiff′ee, “Evaluation and Modeling of the Cell Resistance in Anode-Supported Solid Oxide Fuel Cells,” J. Electrochem. Soc., vol. 155, no. 1, p. B36, 2008.
J. Macdonald, “Comparison of Parametric and Nonparametric Methods for the Analysis and Inversion of Immittance Data: Critique of Earlier Work,” J. Comput. Phys., vol. 157, no. 1, pp. 280-301, January 2000.
B. Manikandan, V. Ramar, C. Yap, and P. Balaya, “Investigation of physico-chemical processes in lithium-ion batteries by deconvolution of electrochemical impedance spectra,” J. Power Sources, vol. 361, pp. 300-309, September 2017.
M. Saccoccio, T. H. Wan, C. Chen, and F. Ciucci, “Optimal Regularization in Distribution of Relaxation Times applied to Electrochemical Impedance Spectroscopy: Ridge and Lasso Regression Methods-A Theoretical and Experimental Study,” Electrochim. Acta, vol. 147, pp. 470-482, November 2014.
J. P. Schmidt, T. Chrobak, M. Ender, J. Illig, D. Klotz, and E. Ivers-Tiff′ee, “Studies on LiFePO4 as cathode material using impedance spectroscopy,” J. Power Sources, vol. 196, no. 12, pp. 5342-5348, 2011.
J. P. Schmidt, P. Berg, M. Schonleber, A. Weber, and E. Ivers-Tiff′ee, “The distribution of relaxation times as basis for generalized time domain models for Li-ion batteries,” J. Power Sources, vol. 221, pp. 70-77, 2013.
V. Sonn, A. Leonide, and E. Ivers-Tiff′ee, “Combined Deconvolution and CNLS Fitting Approach Applied on the Impedance Response of Technical Ni/8YSZ Cermet Electrodes,” J. Electrochem. Soc., vol. 155, no. 7, p. B675, 2008.
J. Song and M. Z. Bazant, “Electrochemical Impedance Imaging via the Distribution of Diffusion Times,” Phys. Rev. Lett., vol. 120, no. 11, p. 116001, March 2018.
A. B. Tesler, D. R. Lewin, S. Baltianski, and Y. Tsur, “Analyzing results of impedance spectroscopy using novel evolutionary programming techniques,” J ELECTROCERAM, vol. 24, no. 4, pp. 245-260, 2010.
Y. Zhang, Y. Chen, M. Li, M. Yan, M. Ni, and C. Xia, “A high precision approach to reconstruct distribution of relaxation times from electrochemical impedance spectroscopy,” J. Power Sources, vol. 308, pp. 1-6, March 2016.
E. Ivers-Tiff′ee and A. Weber, “Evaluation of electrochemical impedance spectra by the distribution of relaxation times,” J. Ceram. Soc. Japan, vol. 125, no. 4, pp. 193-201, 2017.
J. Macutkevic, J. Banys, and A. Matulis, “Determination of the Distribution of the Relaxation Times from Dielectric Spectra,” NAMC, vol. 9, no. 1, pp. 75-88, January 2004.
A. Mertens and J. Granwehr, “Two-dimensional impedance data analysis by the distribution of relaxation times,” J. Energy Storage, vol. 13, pp. 401-408, October 2017.
T. H. Wan, M. Saccoccio, C. Chen, and F. Ciucci, “Influence of the Discretization Methods on the Distribution of Relaxation Times Deconvolution: Implementing Radial Basis Functions with DRTtools,” Electrochim. Acta, vol. 184, pp. 483-499, December 2015.
J. Winterhalter, D. G. Ebling, D. Maier, and J. Honerkamp, “An improved analysis of admittance data for high resistivity materials by a nonlinear regularization method,” J. Appl. Phys, vol. 82, no. 11, pp. 5488-5495 December 1997.
X. Zhou, J. Huang, Z. Pan, and M. Ouyang, “Impedance characterization of lithium-ion batteries aging under high-temperature cycling: Importance of electrolyte-phase diffusion,” J. Power Sources, vol. 426, pp. 216-222, June 2019.
A. Stacy, M. Gilaki, E. Sahraei, and D. Soudbakhsh, “Investigating the Effects of Mechanical Damage on Electrical Response of Li-lon Pouch Cells,” in ACC′20, Denver, CO, July 2020, pp. 1715-1720.
M. Derakhshan, M. Gilaki, A. Stacy, E. Sahraei, and D. Soudbakhsh, “Bending detection of li-ion pouch cells using impedance spectra,” Letters Dyn. Sys. Control, vol. 1, no. 3, p. 031005, 2021.
M. E. Orazem, P. Shukla, and M. A. Membrino, “Extension of the measurement model approach for deconvolution of underlying distributions for impedance measurements,” Electrochim. Acta, vol. 47, no. 13-14, pp. 2027-2034 May 2002.
D. Soudbakhsh, M. Gilaki, W. Lynch, P. Zhang, T. Choi, and E. Sahraei, “Electrical Response of Mechanically Damaged Lithium-ion Batteries,” Energies, vol. 13, no. 17, 2020.
J. P. Meyers, M. Doyle, R. M. Darling, and J. Newman, “The Impedance Response of a Porous Electrode Composed of Intercalation Particles,” J. Electrochem. Soc., vol. 147, no. 8, p. 2930, 2000.
M. Derakhshan, E. Sahraei, D. Soudbakhsh, “Detecting mechanical indentation from the time constants of Li-ion batteries”, Cell Reports Physical Science, Volume 3, Issue 11, 2022, 101102, ISSN 2666-3864, https://doi.org/10.1016/j.xcrp.2022.101102.
Smith, B. (2012). Chevrolet Volt Battery Incident Overview Report (DOE NHTSA). Technical Report January.
Williard, N., He, W., Hendricks, C., and Pecht, M. (2013). Lessons learned from the 787 dreamliner issue on lithium-ion battery reliability. Energies 6, 4682-4695. https://doi. org/10.3390/en6094682.
E. Barsoukov, and J. R. Macdonald, eds. (2005). Impedance Spectroscopy: Theory, Experiment, and Applications, Second edition (Wiley-Interscience). https://doi.org/10.1002/0471716243.
Pastor-Fernandez, C., Uddin, K., Chouchelamane, G. H., Widanage, W. D., and Marco, J. (2017). A comparison between electrochemical impedance spectroscopy and incremental capacity-differential voltage as Lion diagnostic techniques to identify and quantify the effects of degradation modes within battery management systems. J. Power Sources 360, 301-318. https://doi.org/10.1016/j.jpowsour.2017.03.042.
Uddin, K., Perera, S., Widanage, W.,Somerville, L., and Marco, J. (2016). Characterising lithium-ion battery degradation through the identification and tracking of electrochemical battery model parameters. Batteries 2, 13. https://doi.org/10.3390/batteries2020013.

Vetter, J., Novak, P., Wagner, M., Veit, C., Mo″ ller, K. C., Besenhard, J., Winter, M.,Wohlfahrt-Mehrens, M., Vogler, C., and Hammouche, A. (2005). Ageing mechanisms in lithium-ion batteries. J. Power Sources 147,269-281. https://doi.org/10.1016/j.jpowsour. 2005.01.006.

Franklin, A. D., and Bruin, H. J. D. (1983). Thefourier analysis of impedance spectra for electroded solid electrolytes. Phys. Stat. Sol. (a) 75, 647-656. https://doi.org/10.1002/pssa. 2210750240.
Boukamp, B. A., and Rolle, A. (2017). Analysisand application of distribution of relaxation times in solid state ionics. Solid State lon 302, 12-18. https://doi.org/10.1016/j.ssi. 2016.10.009.
Buschel, P., Troltzsch, U., and Kanoun, O. (2012). Calculation of the Distribution of Relaxation Times for Characterization of the Dynamic Battery Behavior (IEEE SSD′12), pp. 1-3. https://doi.org/10.1109/SSD.2012.6198129.
Ciucci, F. (2019). Modeling electrochemicalimpedance spectroscopy. Curr Opin Electrochem 13, 132-139. https://doi.org/10.1016/j.coelec.2018.12.003.
Gavrilyuk, A. L., Osinkin, D. A., and Bronin, D. I. (2017). The use of Tikhonov regularization method for calculating the distribution function of relaxation times in impedance spectroscopy. Russ. J. Electrochem. 53, 575-588. https://doi. org/10.1134/S1023193517060040.
Illig, J., Schmidt, J., Weiss, M., Weber, A., andlvers-Tiffee, E. (2013). Understanding the impedance spectrum of 18650 LiFePO₄-cells. J. Power Sources 239, 670-679. https://doi.org/10.1016/j.jpowsour.2012.12.020.
Kobayashi, K., and Suzuki, T. S. (2018). Distribution of relaxation time analysis for nonideal immittance spectrum: discussion and progress. J. Phys. Soc. Jpn. 87, 094002. https://doi.org/10.7566/JPSJ.87.094002.
Leonide, A., Sonn, V., Weber, A., and IversTiffe'e, E. (2008). Evaluation and modeling of the cell resistance in anode-supported solid oxide fuel cells. J. Electrochem. Soc. 155, B36. https://doi.org/10.1149/1.2801372.
Schichlein, H., Ller, A. C. M., and Voigts, M. (2002). Deconvolution of electrochemical impedance spectra for the identification of electrode reaction mechanisms in solid oxide fuel cells. J. Appl. Electrochem. 32, 875-882. https://doi.org/10.1023/A: 1020599525160.
Shafiei Sabet, P., and Sauer, D. U. (2019). Separation of predominant processes in electrochemical impedance spectra of lithiumion batteries with nickel-manganese-cobalt cathodes. J. Power Sources 425, 121-129. https://doi.org/10.1016/j.jpowsour.2019.03.068.
Zhang, Y., Chen, Y., Li, M., Yan, M., Ni, M., andXia, C. (2016). A high-precision approach to reconstruct distribution of relaxation times from electrochemical impedance spectroscopy. J. Power Sources 308, 1-6. https://doi.org/10.1016/j.jpowsour.2016.01.067.
lurilli, P., Brivio, C., and Wood, V. (2021). On theuse of electrochemical impedance spectroscopy to characterize and model the aging phenomena of lithium-ion batteries: a critical review. J. Power Sources 505, 229860. https://doi.org/10.1016/j.jpowsour.2021.229860.
Shafiei Sabet, P., Stahl, G., and Sauer, D. U. (2020). Non-invasive investigation of predominant processes in the impedance spectra of high energy lithium-ion batteries with nickel-cobalt-aluminum cathodes. J. Power Sources 472, 228189. https://doi.org/10.1016/j.jpowsour.2020.228189.
Derakhshan, M., and Soudbakhsh, D. (2022). Temperature-dependent time constants of li-ion batteries. IEEE Control Syst. Lett. 6, 2012-2017. https://doi.org/10.1109/LCSYS.2021.3138036.
Macutkevic, J., Banys, J., and Matulis, A. (2004). Determination of the distribution of the relaxation times from dielectric spectra. NAMC 9, 75-88. https://doi.org/10.15388/NA.2004.9.1.15172.
Mertens, A., and Granwehr, J. (2017). Two dimensional impedance data analysis by the distribution of relaxation times. J. Energy Storage 13, 401-408. https://doi.org/10.1016/j. est.2017.07.029.
Wan, T. H., Saccoccio, M., Chen, C., and Ciucci, F. (2015). Influence of the discretization methods on the distribution of relaxation times deconvolution: implementing radial basis functions with DRTtools. Electrochim. Acta 184, 483-499. https://doi.org/10.1016/j.electacta. 2015.09.097.
Winterhalter, J., Ebling, D., Maier, D., andHonerkamp, J. (1997). An improved analysis of admittance data for high resistivity materials by a nonlinear regularization method. J. Appl. Phys. 82, 5488-5495. https://doi.org/10.1063/1.365577.
Hansen, J. K., Hogue, J. D., Sander, G. K., Renaut, R. A., and Popat, S. C. (2015). Nonnegatively constrained least squares and parameter choice by the residual periodogram for the inversion of electrochemical impedance spectroscopy data. J. Comput. Appl. Math.278, 52-74. https://doi.org/10.1016/j.cam. 2014.09.017.
Boukamp, B. A. (2015). Fourier transformdistribution function of relaxation times; application and limitations. Electrochim. Acta 154, 35-46. https://doi.org/10.1016/j.electacta. 2014.12.059.
Heins, T. P., Schlu “ter, N., Ernst, S. T., and Schro” der, U. (2020). On the interpretation of impedance spectra of large-format lithium-ion batteries and its application in aging studies. Energy Technol. 8, 1900279. https://doi.org/10.1002/ente.201900279.
Tuncer, E., and Gubanski, S. (2001). Ondielectric data analysis. Using the Monte Carlo method to obtain relaxation time distribution and comparing non-linear spectral function fits. IEEE Trans. Dielect. Electr. Insul. 8, 310-320. https://doi.org/10.1109/94.933337.
Tuncer, E., and Macdonald, J. R. (2006). Comparison of methods for estimating continuous distributions of relaxation times. J. Appl. Phys. 99, 074106. https://doi.org/10.1063/1.2188053.
Horlin, T. (1993). Maximum entropy in impedance spectroscopy of non-inductive systems. Solid State lon 67, 85-96. https://doi.org/10.1016/0167-2738 (93) 90313-R.
Horlin, T. (1998). Deconvolution and maximum entropy in impedance spectroscopy of noninductive systems. Solid State lon 107, 241-253. https://doi.org/10.1016/S01672738 (98) 00008-3.
Drach, Z., Hershkovitz, S., Ferrero, D., Leone, P., Lanzini, A., Santarelli, M., and Tsur, Y. (2016). Impedance spectroscopy analysis inspired by evolutionary programming as a diagnostic tool for SOEC and SOFC. Solid State lon 288, 307-310. https://doi.org/10.1016/j.ssi.2016.01.001.
Klotz, D., Schonleber, M., Schmidt, J., and Ivers-Tiffee, E. (2011). New approach for the calculation of impedance spectra out of time domain data. Electrochim. Acta 56, 8763-8769. https://doi.org/10.1016/j.electacta.2011.07.096.
Oz, A., Singh, K., Gelman, D., Thangadurai, V., and Tsur, Y. (2018). Understanding of oxygen reduction reaction on perovskite-type Ba0.5Sr0.5Fe0.91A10.0903-d and
Ba0.5Sr0.5Fe0.8Cu0.203-d using ac impedance spectroscopy genetic programming. J. Phys. Chem. C 122, 15097-15107. https://doi.org/10.1021/acs.jpcc. 8b03036.
Paul, T., and Tsur, Y. (2018). Effect of isovalentdoping on grain boundary conductivity for La2Mo2O9 oxide ion conductor: a distribution function of relaxation times approach. Solid State lon 323, 37-43. https://doi.org/10.1016/j.ssi.2018.05.011.
Hansen, P. C. (1992). Analysis of discrete ill-posed problems by means of the L-curve. SIAM Rev. 34, 561-580. https://doi.org/10.1137/1034115.
Meyers, J. P., Doyle, M., Darling, R. M., and Newman, J. (2000). The impedance response of a porous electrode composed of intercalation particles. J. Electrochem. Soc. 147, 2930. https://doi.org/10.1149/1.1393627.
Stacy, A., Gilaki, M., Sahraei, E., Soudbakhsh, D., 2020. Investigating the Effects of Mechanical Damage on Electrical Response of Li-lon Pouch Cells, in: ACC′20, Denver, CO. pp. 1715-1720. doi: 10.23919/ACC45564.2020.9147883.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention.

What is claimed is:

1. A system for detecting mechanical damage in an energy storage device, comprising:
an impedance analyzer;
an electrical terminal electrically connected to the analyzer; and
a computing system communicatively connected to the analyzer or electrical terminal, comprising a processor and a non-transitory computer-readable medium with instructions stored thereon, which when executed by a processor, perform steps comprising:
performing Electrochemical Impedance Spectroscopy (EIS) with Dynamic Relaxation Time (DRT) to calculate an impedance spectrum of an energy storage device connected to the electrical terminal; and
modeling the energy storage device based on the impedance spectrum to identify if the energy storage device is mechanically damaged.

2. The system of claim 1, further comprising an environment chamber wherein the environment chamber is configured to control the environmental conditions surrounding the energy storage device and the temperature of the energy storage device.

3. The system of claim 1, wherein the system is configured to perform EIS with DRT at a frequency greater than or equal to 1000 Hz.

4. The system of claim 1, wherein the system is configured to model the energy storage device based on only a portion of the EIS spectrum.

5. The system of claim 4, wherein the portion of the EIS spectrum is a high-frequency portion in the range of 0.1 kHz to 100 kHz.

6. The system of claim 4, wherein the portion of the EIS spectrum is a high-frequency portion in the range of 2 kHz to 47 kHz.

7. The system of claim 4, wherein the determination of if the energy storage device is safe is based on DRT or a machine learning method.

8. A method for detecting mechanical damage in an energy storage device, comprising:
applying an input at a range of frequencies to an energy storage device;
measuring an output from the energy storage device;
performing Electrochemical Impedance Spectroscopy (EIS) with Dynamic Relaxation Time (DRT) to calculate an impedance spectrum of the energy storage device; and
modeling the energy storage device based on the impedance spectrum to identify if the energy storage device is mechanically damaged.

9. The method of claim 8, wherein the applied input is a voltage or current.

10. The method of claim 8, wherein the applied input is in sinusoidal or pulsed form.

11. The method of claim 8, wherein the output from the energy storage device is a voltage or current.

12. The method of claim 8, further comprising the step of changing a temperature of the energy storage device to a specific temperature.

13. The method of claim 8, further comprising performing EIS on a frequency range to derive a temperature of the energy storage device based on the state of charge of the energy storage device.

14. The method of claim 8, wherein the method is performed in situ.

15. The method of claim 8, further comprising the step of calculating a state of charge (SOC) of the energy storage device.

16. The method of claim 8, further comprising the step of calculating a state of health (SOH) of the energy storage device.

17. The method of claim 8, further comprising the step of calculating an age of the energy storage device.

18. The method of claim 8, wherein the EIS with DRT is performed at a frequency greater than or equal to 1000 Hz.

19. The method of claim 8, wherein the method is non-invasive and non-destructive.

20. The method of claim 8, wherein the method is performed in situ.
